(19) United States
(12) Patent Application Publication
(10) Pub. No.: US 2026/0006993 A1
(43) Pub. Date: Jan. 1, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Kong-Beng THEI, Hsinchu (TW); Jing-Jung HUANG, Hsinchu (TW); Kuei-Kai HOU, New Taipei City (TW); Wen Han HSIEH, Taipei City (TW)

(21) Appl. No.: 18/760,276

(22) Filed: Jul. 1, 2024

(51) Int. Cl. H10K 59/122; H10K 59/12; H10K 59/80

(52) U.S. Cl. CPC H10K 59/122; H10K 59/1201; H10K 59/80515

(57) ABSTRACT

A semiconductor device (e.g., a microdisplay device) includes isolation structures around subpixels of at least a portion of the display pixels in the display pixel array of the semiconductor device. The isolation structures (e.g., isolation trenches, isolation rings) confine the light generated by the subpixels, enabling the light generated by the subpixels to be highly contained and collimated. Thus, the isolation structures reduce lateral dispersion of the light emitted by the subpixels, which reduces the amount of color mixing between the subpixels. This enables the display pixel array to generate images and/or video with highly accurate color representation and high contrast, among other examples.

### BACKGROUND

A microdisplay device is a type of display device that is formed on a semiconductor wafer. Microdisplay devices enable organic displays to be integrated with complementary metal-oxide-semiconductor (CMOS) technology to achieve low power consumption, high resolution, fast response time, and high contrast. Microdisplay devices have use cases such as camera sensors, near-to-eye (NTE) displays, and/or projection systems, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a subpixel circuit described herein.

FIGS. 2A-2C are diagrams of an example of a semiconductor device described herein.

FIG. 3 is a diagram of an example implementation of subpixels in a display pixel of a semiconductor device described herein.

FIGS. 4A and 4B are diagrams of an example of a display operation of display pixels of a semiconductor device described herein.

FIGS. 5A-5D are diagrams of an example implementation of forming a portion of a semiconductor device described herein.

FIGS. 6A-6I are diagrams of an example implementation of forming a portion of a semiconductor device described herein.

FIG. 7 is a flowchart of an example process associated with forming a semiconductor device described herein.

FIG. 8 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A microdisplay device may include a display pixel array above an interconnect layer of the microdisplay device. The interconnect layer electrically connects the display pixel array to integrated circuits in a semiconductor layer of the microdisplay device that controls the operation of the display pixel array. The display pixel array generates light through emission of photons that are generated by an organic emissive layer stack between a set of electrodes. The electrodes generate an electric current (e.g., through control of the integrated circuits in the semiconductor layer) that stimulates the organic emissive layer stack, and the organic emissive layer stack emits photons basted on the stimulation.

A display pixel in the display pixel array may include a plurality of subpixels that each have a different type of color filter. For example, a red, green, blue (RGB) display pixel may include red, green, and blue subpixels that respectively have red, green, and blue color filters for filtering particular wavelengths of light generated by the display pixel. The subpixels of the display pixel may be activated in various combinations to achieve an overall color for the light emitted by the display pixel.

In some cases, color mixing between subpixels in a display pixel may occur. Color mixing refers to light generated by one subpixel passing through the color filter of another subpixel due to lateral dispersion of the light. Color mixing may result in inaccurate color representation for the display pixel. If color mixing occurs across the display pixel array, the image or video presented by the display pixel array may exhibit inaccurate color representation of the content being displayed and/or may exhibit low contrast, among other examples.

In some implementations described herein, a semiconductor device (e.g., a microdisplay device) includes isolation structures around subpixels of at least a portion of the display pixels in the display pixel array of the semiconductor device. The isolation structures (e.g., isolation trenches, isolation rings) confine the light generated by the subpixels, enabling the light generated by the subpixels to be highly contained and collimated. Thus, the isolation structures reduce lateral dispersion of the light emitted by the subpixels, which reduces the amount of color mixing between the subpixels. This enables the display pixel array to generate images and/or video with highly accurate color representation and high contrast, among other examples.

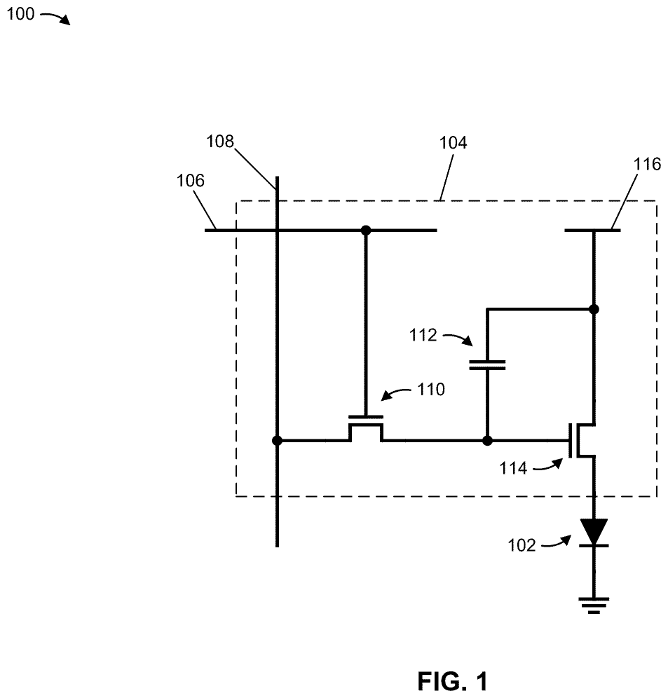

FIG. 1 is a diagram of an example of a subpixel circuit 100 described herein. The subpixel circuit 100 may include a subpixel 102 configured to generate light, and a drive circuit 104 electrically coupled to the subpixel 102. The subpixel 102 may include a light-emitting diode (LED) based subpixel such as an organic LED (OLED) subpixel, among other examples. The drive circuit 104 may include a combination of active integrated circuit devices and passive integrated circuit devices configured to control access to, and the operation of, the subpixel 102. Thus, the subpixel circuit 100 may include an active matrix OLED (AMOLED) pixel circuit.

The drive circuit 104 is electrically coupled to a scan line 106 and a data line 108. The scan line 106 and the data line 108 enable the subpixel circuit 100 to be independently selected and activated among a matrix of a plurality of subpixel circuits 100 in a display pixel array. The scan line 106 is electrically coupled to a gate of a switching transistor 110 in the drive circuit 104. The data line 108 is electrically coupled to a source/drain of the switching transistor 110. “Source/drain” refers to a source, a drain, or a combination of a source and drain, depending on the context. The switching transistor 110 enables the subpixel 102 to be selectively turned on or off. For example, a signal may be selectively applied to the gate of the switching transistor 110 through the scan line 106 to selectively activate or deactivate the subpixel circuit 100.

Another source/drain of the switching transistor 110 is electrically coupled to a storage capacitor 112 and a driving transistor 114. The storage capacitor 112 and a source/drain of the driving transistor 114 are electrically coupled to a current source 116. The driving transistor 114 drives the subpixel 102 based on the current provided from the current source 116. The magnitude of the current provided to the subpixel 102 (and thus, the brightness of the subpixel 102) may be controlled by the gate of the driving transistor 114. In particular, a drive signal may be provided to the gate of the driving transistor 114 from the data line 108 through the switching transistor 110 to control the magnitude of the current provided to the subpixel 102. The storage capacitor 112 may be included to stabilize the drive signal and, therefore, the brightness of the subpixel 102, and to reduce and/or minimize flicker for the subpixel 102.

The transistors in the drive circuit 104, including the switching transistor 110 and the driving transistor 114, may be physically implemented as thin-film transistors (TFTs), fin field effect transistors (finFETs), nanostructure transistors (e.g., nanowire transistors, nanosheet transistors, gate-all-around (GAA) transistors, multi-bridge channel transistors, nanoribbon transistors), and/or another type of transistor structure. The capacitors in the drive circuit 104, including the storage capacitor 112, may be physically implemented as planar metal-insulator-metal (MIM) capacitors, deep trench capacitors (DTCs), and/or another type of capacitor structure.

In some implementations, a plurality of subpixel circuits 100 may be physically grouped and/or logically grouped together to form a display pixel in a display pixel array. Each of the subpixel circuits 100 of the display pixel may be configured to generate light of a particular color. The subpixel circuits 100 of the display pixel may be independently controlled and driven such that the colors of the subpixel circuits 100 can be mixed to generate a wide gamut of color for the display pixel.

As indicated above, FIG. 1 is provided as an example. Other examples may differ from what is described with regard to FIG. 1. In particular, other configurations for a subpixel circuit 100 are within the scope of the present disclosure. The drive circuit 104 may include different components, different quantities of components, and/or differently arranged and/or connected components than those illustrated in FIG. 1. Additional components may be included in the drive circuit 104 for achieving luminance compensation, increased frame rates, and/or for another function.

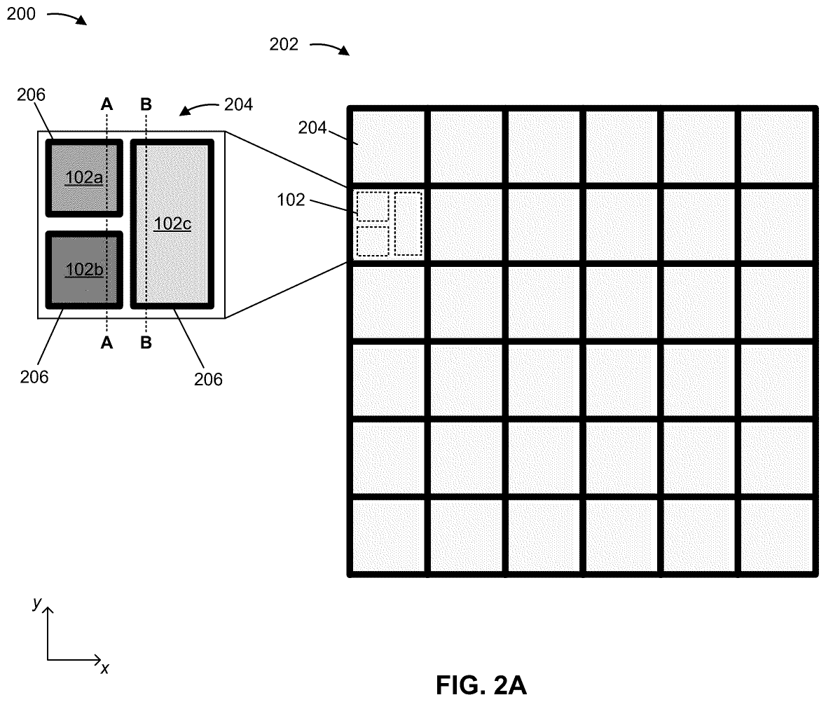

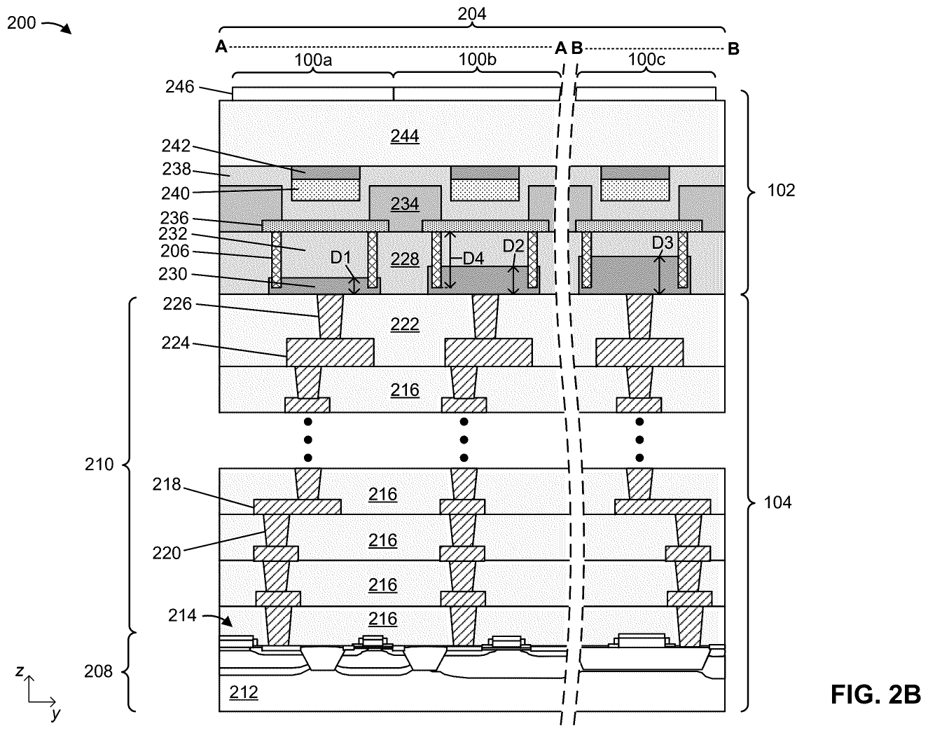

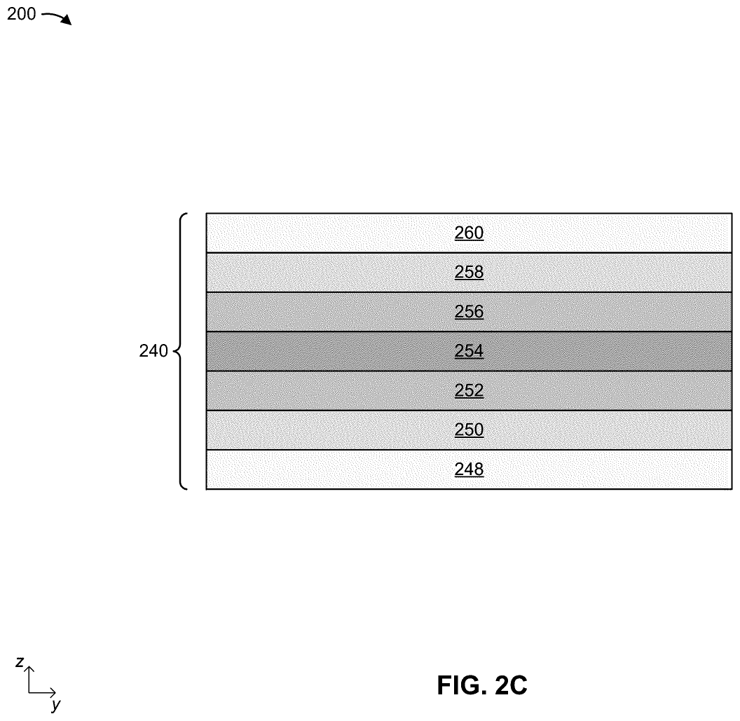

FIGS. 2A-2C are diagrams of an example of a semiconductor device 200 described herein. FIG. 2A illustrates a top view of the semiconductor device 200. As shown in FIG. 2A, the semiconductor device 200 may include a display device that includes a display pixel array 202. The display pixel array 202 includes a plurality of display pixels 204 configured to collectedly generate an image and/or video. In some implementations, the display pixels 204 are arranged in a grid, as shown in the example in FIG. 2A. However, other arrangements of display pixels 204 for the display pixel array 202 are within the scope of the present disclosure. In some implementations, the display pixels 204 include OLED display pixels, and the display pixel array 202 includes an OLED display. However, other types of display pixels and display pixel arrays are within the scope of the present disclosure.

As further shown in FIG. 2A, a display pixel 204 may include a plurality of subpixels 102. For example, a display pixel 204 may include a subpixel 102a that is configured to emit light of a first color (e.g., red light), a subpixel 102a that is configured to emit light of a second color (e.g., green light), and subpixel 102a that is configured to emit light of a third color (e.g., blue light). However, other configurations and combinations of subpixels 102 for the display pixels 204 are within the scope of the present disclosure. Two or more subpixels 102 of a display pixel 204 may be the same size and/or shape, two or more subpixels 102 of a display pixel 204 may be different sizes and/or different shapes, or a combination thereof.

As further shown in FIG. 2A, isolation structures 206 are included around one or more of the subpixels 102a-102c in a display pixel 204. An isolation structure 206 may be included around a perimeter of a subpixel 102 of a display pixel 204 to confine the light emitted by the subpixel 102 and to prevent, minimize, and/or otherwise reduce diffusion of the light emitted by the subpixel 102 into areas of the display pixel 204 occupied by the other subpixels 102 of the display pixel 204. For example, an isolation structure 206 may be included around a perimeter of a subpixel 102a of a display pixel 204 to prevent, minimize, and/or otherwise reduce diffusion of the light emitted by the subpixel 102a into subpixels 102b and 102c of the display pixel 204. As another example, an isolation structure 206 may be included around a perimeter of the subpixel 102b of a display pixel 204 to prevent, minimize, and/or otherwise reduce diffusion of the light emitted by the subpixel 102b into the subpixels 102a and 102c of the display pixel 204. As another example, an isolation structure 206 may be included around a perimeter of the subpixel 102c of a display pixel 204 to prevent, minimize, and/or otherwise reduce diffusion of the light emitted by the subpixel 102c into the subpixels 102a and 102b of the display pixel 204.

An isolation structure 206 may include a closed-loop isolation structure that fully encircles the perimeter of an associated subpixel 10

2. An isolation structure 206 may include a closed-loop trench (e.g., a deep trench isolation (DTI) structure) and/or another type of structure that is elongated in a z-direction (e.g., a vertical direction) in the semiconductor device 200. The top view shape of the isolation structure 206 may conform to the shape of the subpixel 102, and may include a closed-loop isolation ring, a closed loop isolation square, a closed-loop isolation rectangle, and/or another closed-loop shape.

In some implementations, an isolation structure 206 includes one or more materials having low reflectivity in the visible light spectrum to minimize blooming and other types of display degradation in images and/or video generated by the display pixel array 202. For example, an isolation structure 206 may include titanium nitride (TiN) (e.g., having a specular reflectance of approximately 50% or less in a visible light spectrum of approximately 380 nanometers to approximately 750 nanometers). In some implementations, an isolation structure 206 includes one or more materials having high reflectivity in the visible light spectrum to achieve low optical loss and enable a high amount of display brightness to be achieved for the display pixel array 202. For example, an isolation structure 206 may include copper (Cu), aluminum (Al), and/or tungsten (W), among other examples.

FIG. 2B illustrates cross-section views of an example display pixel 204 along line A-A and line B-B in FIG. 2A. The cross-section views in FIG. 2B illustrate an example structural arrangement of subpixel circuits 100a-100c for the subpixels 102a-102c of the display pixel 204. As shown in FIG. 2B, the semiconductor device 200 may include a microdisplay device in that the subpixels 102 of the display pixel array 202 are included on the semiconductor device 200. Thus, the semiconductor device 200 may include an OLED-on-silicon device, a display-on-silicon device, and/or another type of microdisplay device in which a display pixel array 202 is integrated on a semiconductor device with CMOS integrated circuits.

As shown in FIG. 2B, the subpixels 102 of the display pixel array 202 are included above a device layer 208 and an interconnect layer 210 of the semiconductor device 200. The device layer 208 may include a semiconductor layer 212 corresponding to a portion of a semiconductor wafer on which the semiconductor device 200 was formed. The semiconductor layer 212 may include a silicon (Si) substrate, a substrate formed of a material including silicon, a III-V compound semiconductor material substrate such as gallium arsenide (GaAs), a silicon on insulator (SOI) substrate, or another type of semiconductor substrate.

The device layer 208 includes integrated circuit devices 214 in and/or on the semiconductor layer 212. The integrated circuit devices 214 may include, for example, the components of the drive circuits 104 of the subpixel circuits 100a-100c of the display pixel 204. For example, the integrated circuit devices 214 may include the switching transistors 110, the storage capacitors 112, the driving transistors 114, and/or other components of the drive circuits 104. The transistors (e.g., the switching transistors 110, the driving transistors 114) of the drive circuits 104 may be implemented as planar transistors, finFETs, GAA transistors, and/or another type of transistors in and/or on the semiconductor layer 212.

The interconnect layer 210 includes conductive structures that interconnect the integrated circuit devices 214 of the drive circuits 104, and electrically connect the integrated circuit devices 214 of the drive circuits 104 with the subpixels 102 of the subpixel circuits 100a-100c. The interconnect layer 210 includes one or more dielectric layers 216 that are arranged in a direction (e.g., z-direction) that is approximately perpendicular to the semiconductor layer 212. The dielectric layer(s) 216 may each include backend dielectric layers (e.g., interlayer dielectric (ILD) layers, intermetal dielectric (IMD) layers) and etch stop layers (ESLs) that are arranged in an alternating manner in the interconnect layer 210. The dielectric layer(s) 216 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The conductive structures in the dielectric layer(s) 216 of the interconnect layer 210 may include metallization layers 218 (e.g., trenches, conductive lines) that are interconnected by layer-to-layer connection structures 220 (e.g., vias). The metallization layers 218 and layer-to-layer connection structures 220 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive structures of the interconnect layer 210 may be arranged in a vertical manner (e.g., in the z-direction) to facilitate electrical signals and/or power to be routed between the integrated circuit devices 214 in the device layer 208 and the subpixels 102 above the interconnect layer 210, and/or between integrated circuit devices 214 through the interconnect layer 210. The conductive structures may be arranged in alternating layers of metallization layers 218 (referred to as “M”-layers) and layer-to-layer connection structures 220 (referred to as “V”-layers). Each layer of metallization layers 218 (e.g., each M-layer) may include one or more metallization layers 218 laterally arranged in the interconnect layer 210, and each layer of layer-to-layer connection structures 220 (e.g., each V-layer) may include one or more layer-to-layer connection structures 220 that interconnect the metallization layers 218 between vertically adjacent layers of metallization layers 218 in the interconnect layer 210. As an example, a metal-0 (M0) layer may be located at the bottom of the interconnect layer 210 and may be coupled with the integrated circuit devices 214 in the device layer 208, a via-1 (V1) layer may be located above and coupled with the M1 layer in the interconnect layer 210, a metal-1 layer (M1) layer may be located above and coupled with the V1 layer in the interconnect layer 210, a via-2 (V2) layer may be located above and coupled with the M1 layer in the interconnect layer 210, a metal-2 layer (M2) layer may be located above and electrically coupled with the V2 layer in the interconnect layer 210, and so on. In some implementations, the interconnect layer 210 includes nine (9) stacked metallization layers (e.g., M0-M8). In some implementations, the interconnect layer 210 includes another quantity of stacked metallization layers.

At the top of the interconnect layer 210 is a passivation layer 222, top metal pads 224 in the passivation layer 222, and top metal vias 226 on the top metal pads 224 in the passivation layer 222. The passivation layer 222 may include an oxide (e.g., a silicon oxide (SiOₓ) and/or another oxide material), USG, an ELK dielectric material, and/or another suitable dielectric material. The top metal pads 224 and the top metal vias 226 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

As further shown in FIG. 2B, the subpixels 102 of the display pixel 204 are included above the interconnect layer 210 of the semiconductor device 200. A portion of the subpixels 102 is included in a cavity oxide layer 228 above the passivation layer. The cavity oxide layer 228 may include a silicon oxide (SiOₓ such as SiO₂) and/or another optically transparent (or semi-transparent) dielectric material.

Each subpixel 102 may include a first electrode 230 (e.g., an anode) at the bottom of the cavity oxide layer 228. The first electrodes 230 may be included on the passivation layer 222 and may be electrically connected to the top metal vias 226 of the interconnect layer 210. This enables electrical inputs to be applied from the drive circuits 104 to the subpixels 102 through the first electrodes 230. The first electrodes 230 may be referred to as bottom electrodes and may include one or more reflective materials such as aluminum (Al), tungsten (W), and/or copper (Cu), among other examples. The reflective materials of the first electrodes 230 enable the first electrodes 230 to reflect light emitted by the subpixels 102 (e.g., to reflect the light upward) to minimize the amount of light that is lost into the interconnect layer 210.

As shown in FIG. 2B, the first electrodes 230 each have a z-direction (vertical) thickness, including a first thickness (indicated in FIG. 2B as dimension D1) for the first electrode 230 of a subpixel 102 of the subpixel circuit 100a, a second thickness (indicated in FIG. 2B as dimension D2) for the first electrode 230 of a subpixel 102 of the subpixel circuit 100b, and a third thickness (indicated in FIG. 2B as dimension D3) for the first electrode 230 of a subpixel 102 of the subpixel circuit 100c, among other examples. In some implementations, the first electrodes 230 in two or more subpixels 102 are formed to approximately a same z-direction thickness. For example, the dimension D1, the dimension D2, and the dimension D3 may all be approximately equal.

In some implementations, the first electrodes 230 in two or more subpixels 102 are formed to different z-direction thicknesses. This enables different z-direction thicknesses to be achieved for resonant cavities 232 for the subpixels 102 to be achieved. The resonant cavity 232 of a subpixel 102 includes a dielectric region (e.g., a resonant region) of the cavity oxide layer 228 above first electrode 230 of the subpixel 102 in which particular wavelengths of light generated by subpixels 102 may be amplified. The top surface of the cavity oxide layer 228 may be substantially flat and uniform across the cavity oxide layer 228. Moreover, the bottom surfaces of the first electrodes 230 of the subpixels 102 may be approximately co-planar. Thus, the thickness of a resonant cavity 232 for a subpixel 102 is based on the z-direction thickness of a first electrode 230 of a subpixel 102. The greater the thickness of a first electrode 230 of a subpixel 102, the lesser the z-direction thickness of the resonant cavity 232 of the subpixel 102. Conversely, the lesser the thickness of a first electrode 230 of a subpixel 102, the greater the z-direction thickness of the resonant cavity 232 of the subpixel 102.

As an example, the first electrode 230 for the subpixel 102 of the subpixel circuit 100c may be formed such that the z-direction thicknesses (dimension D3) of the first electrode 230 for the subpixel 102 of the subpixel circuit 100c is greater than the z-direction thicknesses (dimension D2) of the first electrode 230 for the subpixel 102 of the subpixel circuit 100b, and is greater than the z-direction thicknesses (dimension D1) of the first electrode 230 for the subpixel 102 of the subpixel circuit 100a. This results in the z-direction thickness of the resonant cavity 232 of the subpixel 102 of the subpixel circuit 100c being configured to amplify shorter wavelengths of light (e.g., blue light) than the subpixels 102 for the subpixel circuits 100a and 100b.

As another example, the first electrode 230 for the subpixel 102 of the subpixel circuit 100a may be formed such that the z-direction thicknesses (dimension D1) of the first electrode 230 for the subpixel 102 of the subpixel circuit 100a is less than the z-direction thicknesses (dimension D2) of the first electrode 230 for the subpixel 102 of the subpixel circuit 100b, and is less than the z-direction thicknesses (dimension D3) of the first electrode 230 for the subpixel 102 of the subpixel circuit 100c. This results in the z-direction thickness of the resonant cavity 232 of the subpixel 102 of the subpixel circuit 100a being configured to amplify longer wavelengths of light (e.g., red light) than the subpixels 102 for the subpixel circuits 100b and 100c. The bottom surface of the resonance cavity 232 may be located closer to the interconnect layer 210 than the resonance cavities 232 of other subpixels 102.

As another example, the first electrode 230 for the subpixel 102 of the subpixel circuit 100b may be formed such that the z-direction thicknesses (dimension D2) of the first electrode 230 for the subpixel 102 of the subpixel circuit 100b is less than the z-direction thicknesses (dimension D3) of the first electrode 230 for the subpixel 102 of the subpixel circuit 100c, and is greater than the z-direction thicknesses (dimension D1) of the first electrode 230 for the subpixel 102 of the subpixel circuit 100a. This results in the z-direction thickness of the resonant cavity 232 of the subpixel 102 of the subpixel circuit 100a being configured to amplify wavelengths of light (e.g., green light) between the wavelengths of light emitted by the subpixels 102 for the subpixel circuits 100a and 100c.

The different z-direction thicknesses of the first electrodes 230 of the subpixels 102 of the subpixel circuits 100a-100c results in the top surfaces of the first electrodes 230 being located at different vertical (z-direction) heights in the semiconductor device 200. Moreover, the different z-direction thicknesses of the first electrodes 230 of the subpixels 102 of the subpixel circuits 100a-100c results in the bottom surfaces of the resonant cavities 232 being located at different vertical (z-direction) heights in the semiconductor device 200.

For example, the z-direction thicknesses of the first electrode 230 of the subpixel 102 of the subpixel circuits 100b being greater than the z-direction thicknesses of the first electrode 230 of the subpixel 102 of the subpixel circuits 100a (e.g., dimension D2>dimension D1) results in the top surface of the first electrode 230 of the subpixel 102 of the subpixel circuits 100b being located at a greater z-direction height in the semiconductor device 200 than the top surface of the first electrode 230 of the subpixel 102 of the subpixel circuits 100a. As another example, the z-direction thicknesses of the first electrode 230 of the subpixel 102 of the subpixel circuits 100b being greater than the z-direction thicknesses of the first electrode 230 of the subpixel 102 of the subpixel circuits 100a (e.g., dimension D2>dimension D1) results in the bottom surface of the first electrode 230 of the subpixel 102 of the subpixel circuits 100b being located at a lower z-direction position in the semiconductor device 200 than the top surface of the first electrode 230 of the subpixel 102 of the subpixel circuits 100a.

As another example, the z-direction thicknesses of the first electrode 230 of the subpixel 102 of the subpixel circuits 100c being greater than the z-direction thicknesses of the first electrode 230 of the subpixel 102 of the subpixel circuits 100b (e.g., dimension D3>dimension D2) results in the top surface of the first electrode 230 of the subpixel 102 of the subpixel circuits 100c being located at a greater z-direction height in the semiconductor device 200 than the top surface of the first electrode 230 of the subpixel 102 of the subpixel circuits 100b. As another example, the z-direction thicknesses of the first electrode 230 of the subpixel 102 of the subpixel circuits 100c being greater than the z-direction thicknesses of the first electrode 230 of the subpixel 102 of the subpixel circuits 100b (e.g., dimension D3>dimension D2) results in the bottom surface of the first electrode 230 of the subpixel 102 of the subpixel circuits 100c being located at a lower z-direction position in the semiconductor device 200 than the top surface of the first electrode 230 of the subpixel 102 of the subpixel circuits 100b.

As further shown in FIG. 2B, the isolation structures 206 are included above first electrode 230 of the subpixels 102 of the subpixel circuits 100a-100c. The isolation structures 206 may include elongated structures (e.g., deep trenches) that extend from a top of the cavity oxide layer 228 into the cavity oxide layer 228 to the first electrodes 230 of the subpixels 102. An isolation structure 206 may extend to the top surface of a first electrode 230 of a subpixel 102, or into a portion of the first electrode 230, to provide a continuous barrier around the resonant cavity 232 of the subpixel 102. This minimizes the amount of light, emitted by the subpixel 102, that is laterally diffused into adjacent subpixels 102.

The isolation structures 206 may have a z-direction thickness (or z-direction height) indicated in FIG. 2B as dimension D4. In some implementations, the z-direction thicknesses (dimension D4) of the isolation structures 206 of the subpixels 102 in the display pixel 204 are all approximately a same z-direction thickness. In these implementations, the bottom surfaces of the isolation structures 206 may be approximately co-planar and located at approximately a same z-direction depth in the semiconductor device 200. The z-direction thicknesses (dimension D4) of each of the isolation structures 206 of the subpixels 102 in the display pixel 204 may be selected such that the isolation structure 206 for the subpixel 102 with the thinnest first electrode 230 at least lands on the top surface of the first electrode 230. In some implementations, the z-direction thicknesses (dimension D4) of the isolation structures 206 of two or more subpixels 102 in the display pixel 204 are different z-direction thicknesses.

As further shown in FIG. 2B, the subpixels 102 may include a pixel define layer 234, a substrate layer 236, and another pixel define layer 238 that are included to define the locations of light generation film stacks 240 of the subpixels 102. The pixel define layer 234, the substrate layers 236, and the pixel define layer 238 may each include one or more optically transparent materials or semi-transparent materials, such as silicon oxide (SiOₓ such as SiO₂), indium tin oxide (ITO), indium zinc oxide (IZO), and/or another optically transparent (or semi-transparent) material.

The light generation film stacks 240 of the subpixels 102 are included in the pixel define layer 238, along with second electrodes 242 above the light generation film stacks 240. The light generation film stacks 240 each include a plurality of layers of organic materials that are capable of generating and emitting light based on electrical inputs applied to the first electrodes 230 and the second electrodes 242. An example of a light generation film stack 240 is illustrated and described in connection with FIG. 2C. The second electrodes 242 may be referred to as top electrodes and may include one or more optically transparent and electrically conductive materials such as ITO and/or IZO, among other examples.

A passivation layer 244 is included above the second electrodes 242, and color filters 246 are included above the passivation layer 244. A color filter 246 of a subpixel 102 filters particular wavelengths of light emitted by the light generation film stack 240 of the subpixel 102, and allows other wavelengths to pass through the color filter 246. For example, a “blue” color filter 246 allows wavelengths corresponding to blue visible light to pass through the color filter 246 and blocks wavelengths corresponding to other colors of visible light. As another example, a “green” color filter 246 allows wavelengths corresponding to green visible light to pass through the color filter 246 and blocks wavelengths corresponding to other colors of visible light. As another example, a “red” color filter 246 allows wavelengths corresponding to red visible light to pass through the color filter 246 and blocks wavelengths corresponding to other colors of visible light.

FIG. 2C illustrates an example of a light generation film stack 240 that may be included in a subpixel 102 of a display pixel 204 of the display pixel array 202 of the semiconductor device 200. The display pixels 204 in the display pixel array 202 may include OLED pixels. Accordingly, the light generation film stack 240 of a subpixel 102 may include one or more layers of organic material that includes an emissive layer formed of one or more organic materials. The layers may include a hole injection layer 248, a hole transport layer 250 on the hole injection layer 248, an electron blocking layer 252 on the hole transport layer 250, an emissive layer 254 on the electron blocking layer 252, a hole blocking layer 256 on the emissive layer 254, an electron transport layer 258 on the hole blocking layer 256, and/or an electron injection layer 260 on the electron transport layer 258, among other examples.

The hole injection layer 248 is configured to inject holes into the emissive layer 254 through the hole transport layer 250 when an electrical input is applied to the hole injection layer 248 through the first electrode 230 (e.g., an anode) of the subpixel 102. The electron injection layer 260 is configured to inject electrons into the emissive layer 254 through the electron transport layer 258 when an electrical input is applied to the electron injection layer 260 through the second electrode 242 (e.g., a cathode) of the subpixel 102. The hole blocking layer 256 is configured to inhibit holes generated by the hole injection layer 248 from propagating through the emissive layer 254, and the electron blocking layer 252 is configured to inhibit the electrons generated by the electron injection layer 260 from propagating through the emissive layer 254. The emissive layer 254 includes one or more organic materials that are capable of emitting light based on the holes and the electrons injected into the emissive layer 254. For example, the emissive layer 254 may include one or more organic fluorescent emissive materials, and/or one or more phosphorescent emissive materials, among other examples.

As indicated above, FIGS. 2A-2C are provided as examples. Other examples may differ from what is described with regard to FIGS. 2A-2C.

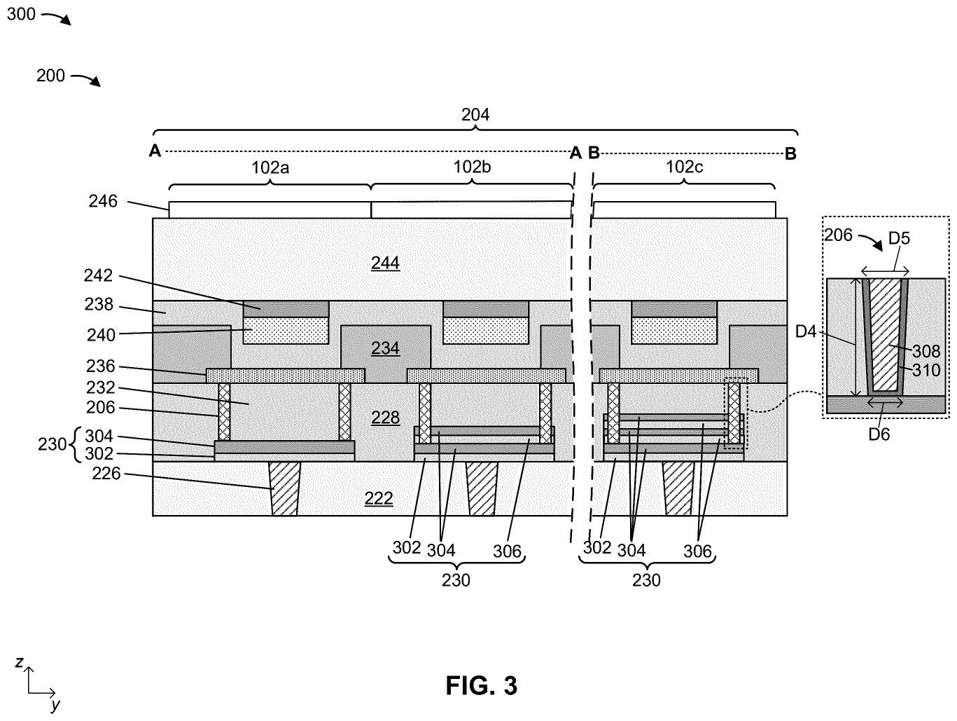

FIG. 3 is a diagram of an example implementation 300 of subpixels 102 in a display pixel 204 of the semiconductor device 200 described herein. In particular, the example implementation 300 includes various examples of first electrodes 230 and isolation structures 206 for the subpixels 102 of the display pixel 204.

As shown in FIG. 3, the first electrodes 230 (e.g., the bottom electrodes or anodes) of the subpixels 102a-102c of a display pixel 204 of the semiconductor device 200 are formed on the passivation layer 222 such that the first electrodes 230 are electrically connected to the top metal vias 226. The first electrodes 230 may be formed to different z-direction thicknesses for different subpixels. This enables different z-direction thicknesses for the resonant cavities for the subpixels to be achieved.

For example, the first electrode 230 for the subpixel 102c may be formed such that the z-direction thicknesses of the first electrode 230 for the subpixel 102c is greater than the z-direction thicknesses of the first electrode 230 for the subpixel 102b and the z-direction thicknesses of the first electrode 230 for the subpixel 102a because of the subpixel 102c being a blue subpixel that is configured to emit shorter wavelength light (e.g., blue light) than the subpixels 102a and 102b. The first electrode 230 for the subpixel 102c is formed such that the size of the resonant cavity for the subpixel 102c facilitates resonance of the wavelengths for the subpixel 102c.

As another example, the first electrode 230 for the subpixel 102b may be formed such that the z-direction thicknesses of the first electrode 230 for the subpixel 102b is greater than the z-direction thicknesses of the first electrode 230 for the subpixel 102a because of the subpixel 102b being a green subpixel that is configured to emit shorter wavelength light (e.g., green light) than the subpixels 102a (e.g., which may be configured to emit red light). The first electrode 230 for the subpixel 102b is formed such that the size of the resonant cavity for the subpixel 102b facilitates resonance of the wavelengths for the subpixel 102b.

As another example, the first electrode 230 for the subpixel 102a may be formed such that the z-direction thicknesses of the first electrode 230 for the subpixel 102a is less than the z-direction thicknesses of the first electrode 230 for the subpixel 102b and the z-direction thicknesses of the first electrode 230 for the subpixel 102c because of the subpixel 102a being a red subpixel that is configured to emit longer wavelength light (e.g., red light) than the subpixels 102b and 102c. The first electrode 230 for the subpixel 102a is formed such that the size of the resonant cavity for the subpixel 102a facilitates resonance of the wavelengths for the subpixel 102a.

A nitride layer 302 may be included on the passivation layer 222. The nitride layer 302 may include tantalum nitride (TaN) and/or another nitride-containing material. The nitride layer 302 may be included as a barrier layer for the first electrodes 230 and/or to promote adhesion between the first electrodes 230 and the passivation layer 222.

As further shown in FIG. 3, each first electrode 230 may include an arrangement of one or more metal layers 304 and one or more nitride layers 306 on the nitride layer 302. For example, the first electrode 230 of the subpixel 102a (e.g., a red subpixel) may include a metal layer 304 on the nitride layer 302. As another example, the first electrode 230 of the subpixel 102b may include a plurality of metal layers 304 and a nitride layer 306 between the metal layers 304. The metal layers 304 and the nitride layer 306 are arranged in an alternating manner in the z-direction in the semiconductor device 200. As another example, the first electrode 230 of the subpixel 102c may include a plurality of metal layers 304 and a plurality of nitride layers 306 between the metal layers 304. The metal layers 304 and the nitride layers 306 are arranged in an alternating manner in the z-direction in the semiconductor device 200.

The alternating arrangement of metal layers 304 and nitride layers 306 enables one or more of the first electrodes 230 to effectively function as multiple-layer mirrors. The metal layers 304 may include one or more reflective metals such as aluminum (Al), molybdenum (Mo), and/or tungsten, among other examples. The nitride layers 306 may include metal nitride layers that include titanium nitride (TiN) and/or another metal nitride. Alternatively, silicon (Si) and/or another material may be used in place of the nitride layers 306.

As further shown in FIG. 3, in some subpixels 102, the bottom surface of the isolation structure 206 may land on the top surface of the topmost metal layer 304 of the first electrode 230. In other subpixels 102, the bottom surface of the isolation structure 206 may extend into the first electrode 230. Thus, the isolation structure 206 may extend through one or more metal layers 304 and/or one or more nitride layers 306 of the first electrode 230.

An isolation structure 206 may include a trench structure that is elongated in the z-direction such that a z-direction thickness (indicated in FIG. 3 as dimension D4) of the isolation structure 206 is greater than a lateral width of the isolation structure 206 at the top of the isolation structure 206 (indicated in FIG. 3 as dimension D5), and is greater than a lateral width of the isolation structure 206 at the bottom of the isolation structure 206 (indicated in FIG. 3 as dimension D6). In some implementations, an isolation structure 206 has a tapered cross-sectional profile such that the lateral width of the isolation structure 206 at the top of the isolation structure 206 (dimension D5) is greater than the lateral width of the isolation structure 206 at the bottom of the isolation structure 206 (dimension D6).

As further shown in FIG. 3, an isolation structure 206 may include an isolation layer 308 and one or more liners 310 between the isolation layer 308 and the cavity oxide layer 228. The isolation layer 308 may include copper (Cu), tungsten (W), titanium nitride (TiN), and/or another suitable material. The one or more liners 310 may include a tantalum nitride (TaN) barrier layer, a tantalum (Ta) barrier layer, a copper (Cu) see layer, and/or another type of liner.

As indicated above, FIG. 3 is provided as an example. Other examples may differ from what is described with regard to FIG. 3.

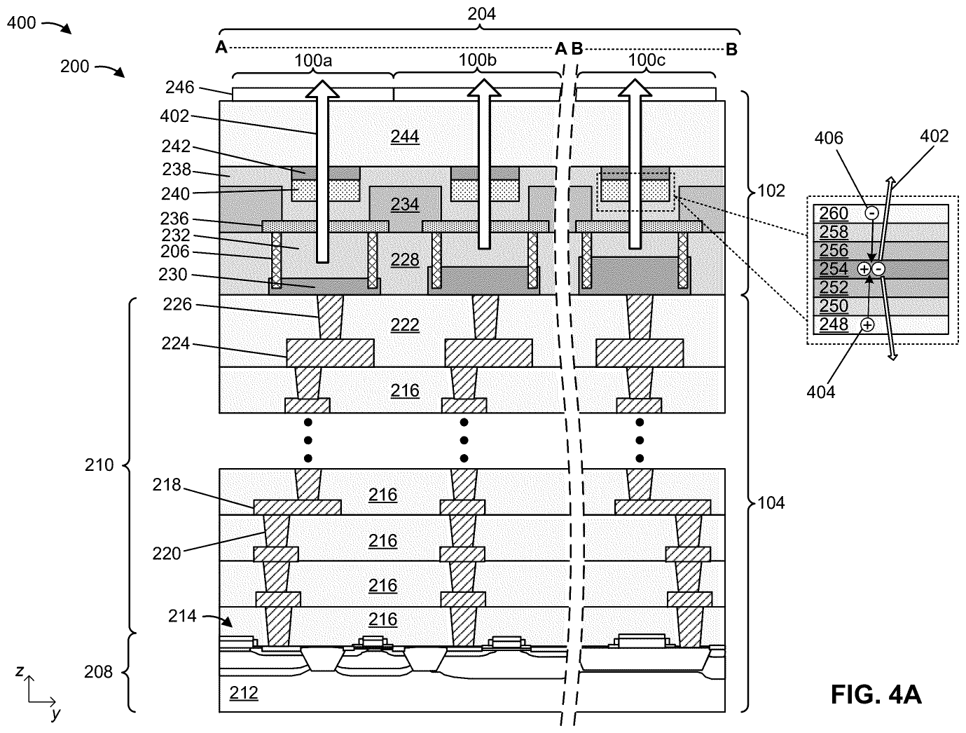

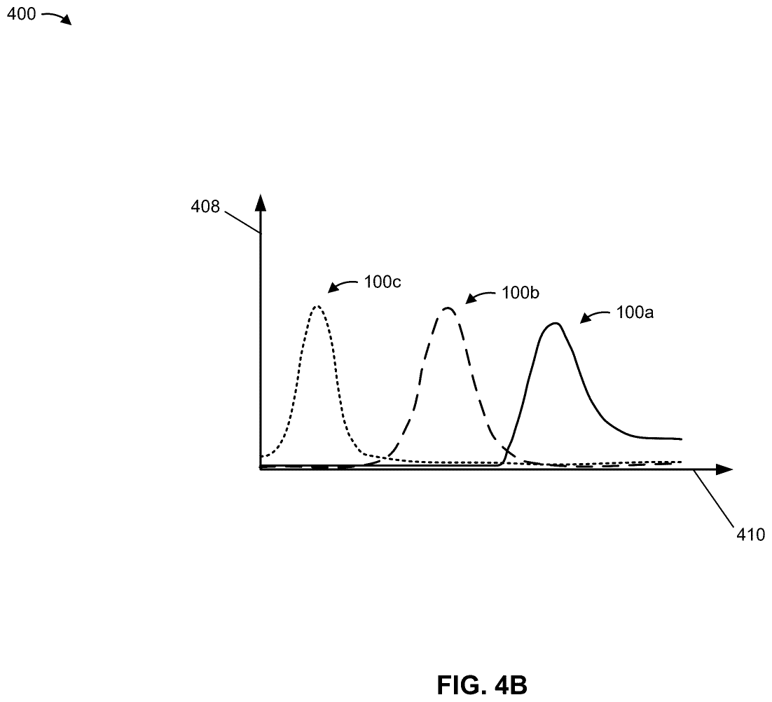

FIGS. 4A and 4B are diagrams of an example 400 of a display operation of display pixels 204 of the semiconductor device 200 described herein. As shown in FIG. 4A, each of the subpixels 102 of a display pixel in the display pixel array 202 of the semiconductor device 200 may be configured to emit light 402. To emit light 402, an electrical input (e.g., an electric current, a voltage) is applied to the first electrode 230 and the second electrode 242 of a subpixel 102. The electrical input may be applied through the drive circuit 104 associated with subpixel 102.

The electrical input applied to the first electrode 230 (e.g., an anode) causes the hole injection layer 248 to inject holes 404 into the emissive layer 254 of the light generation film stack 240 (e.g., the organic film stack) of the subpixel 102 through the hole transport layer 250. The hole blocking layer 256 of the light generation film stack 240 inhibits the holes 404 from propagating through the emissive layer 254. The electrical input applied to the second electrode 242 (e.g., a cathode) causes the electron injection layer 260 to inject electrons 406 into the emissive layer 254 through the electron transport layer 258. The electron blocking layer 252 of the light generation film stack 240 inhibits the electrons 406 from propagating through the emissive layer 254. The injected holes 404 and electrons 406 localize on the same molecule in the emissive layer 254, causing an exciton, which is a localized electron-hole pair having an excited energy state, to be formed. The light 402 is emitted from the subpixel 102 when the exciton relaxes due to photoemission.

The light 402 emitted from a light generation film stack 240 of a subpixel 102 may contain “white light” in that the light 402 contains multiple wavelengths of light across the visible light spectrum. At least a portion of the light 402 propagates downward in the z-direction through the resonance cavity 232 and reflects off of the first electrode 230 (which is reflective), and the first electrode 230 may reflect this light 402 upward toward the color filter 246 of the subpixel 102. The isolation structure 206 that laterally surrounds the resonance cavity 232 confines the light 402 within the subpixel 102 and minimizes the amount of the light 402 that diffuses into adjacent subpixels 102.

The light 402 may propagate through the second electrode 242 (which may be transparent or semi-transparent) and through the color filter 246. The color filter 246 filters the light 402 such that only particular wavelengths of the light 402 pass through the color filter 246 and are emitted from the subpixel 102. The resonance cavity 232 is sized (e.g., in the z-direction) such that these particular wavelengths are amplified.

FIG. 4B illustrates examples of light intensity 408 for different wavelengths 410 of emitted light 402 for subpixels 102a-102c that are configured to emit different colors of visible light. As shown in FIG. 4B, the subpixel 102 of the subpixel circuit 100a may be configured to emit the longest wavelengths of light (e.g., red light), the subpixel 102 of the subpixel circuit 100c may be configured to emit the shortest wavelengths of light (e.g., blue light), and the subpixel 102 of the subpixel circuit 100b may be configured to emit the wavelengths of light (e.g., green light) between the wavelengths of light emitted by the subpixels 102 of the subpixel circuits 100a and 100c. However, the subpixels 102 of the subpixel circuits 100a-100c may be configured to emit other combinations of wavelengths of light.

As further shown in FIG. 4B, including the isolation structures 206 around the perimeter of the first electrodes 230 and laterally around the resonance cavities 232 of the subpixels 102a-102c reduces and/or minimizes mixing (or overlap) of the wavelengths of light emitted by the subpixels 102a-102c. For example, the light emitted by the subpixel 102a may range from approximately 550 nanometers to approximately 650 nanometers, the light emitted by the subpixel 102b may range from approximately 500 nanometers to approximately 650 nanometers, and the light emitted by the subpixel 102c may range from approximately 425 nanometers to approximately 500 nanometers.

As indicated above, FIGS. 4A and 4B are provided as examples. Other examples may differ from what is described with regard to FIGS. 4A and 4B.

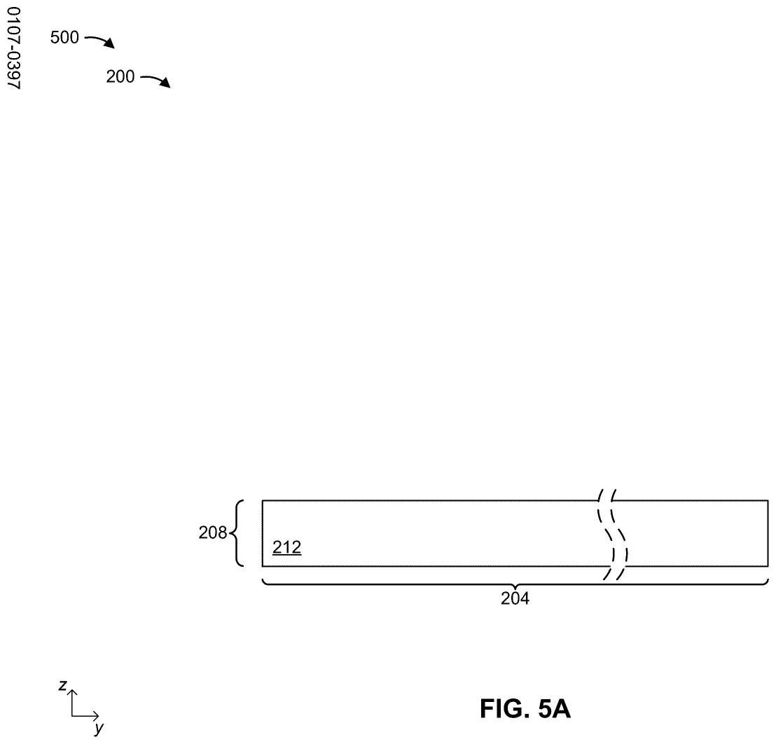

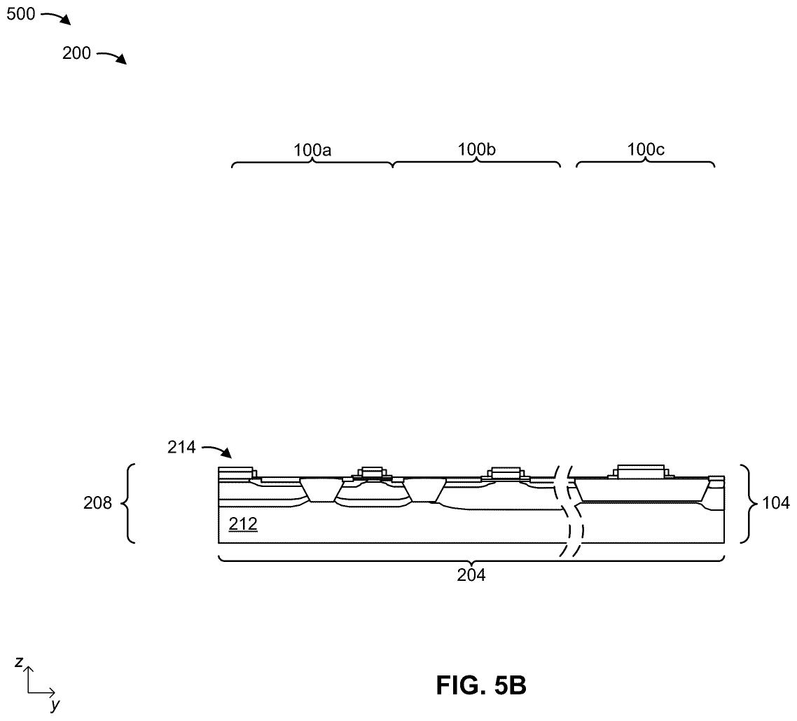

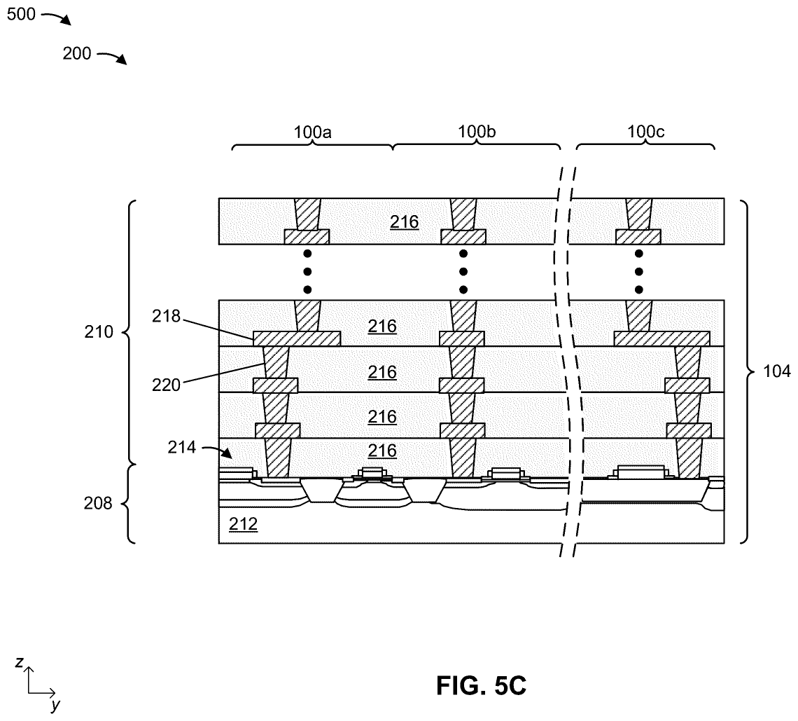

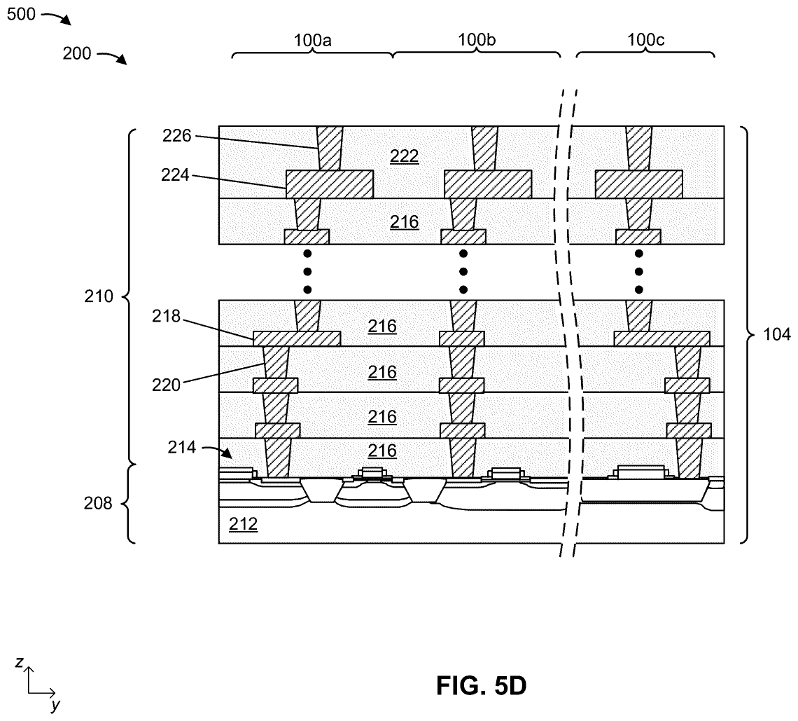

FIGS. 5A-5D are diagrams of an example implementation 500 of forming a portion of the semiconductor device 200 described herein. In particular, the example implementation 500 may include an example of forming the device layer 208 and the interconnect layer 210 of the semiconductor device 200, including the drive circuits 104 of the subpixel circuits 100 of the display pixel array 202 of the semiconductor device 200. In some implementations, one or more semiconductor processing tools may be used to perform one or more of the operations described in connection with the example implementation 500, such as a deposition tool, an exposure tool, a developer tool, an etch tool, a planarization tool, a plating tool, and/or another type of semiconductor processing tool.

Turning to FIG. 5A, the semiconductor layer 212 may be provided. The semiconductor layer 212 may be provided in the form of a semiconductor wafer such as a silicon (Si) wafer, a semiconductor die, and/or another type of semiconductor workpiece.

As shown in FIG. 5B, the integrated circuit devices 214 may be formed in and/or on the semiconductor layer 212 in the device layer 208 of the semiconductor device 200. One or more semiconductor processing tools may be used to form one or more portions of the integrated circuit devices 214. For example, a deposition tool may be used to perform various deposition operations to deposit layers of the integrated circuit devices 214, and/or to deposit photoresist layers for etching the semiconductor layer 212 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer 212 and/or portions of the deposited layers to form the integrated circuit devices 214. As another example, a planarization tool may be used to planarize portions of the integrated circuit devices 214. As another example, a plating tool may be used to deposit metal structures and/or layers of the integrated circuit devices 214. As another example, an ion implantation tool may be used to dope one or more portions of the semiconductor layer 212 to form the integrated circuit devices 214.

As shown in FIG. 5C, the interconnect layer 210 is formed above the device layer 208. The dielectric layer(s) 216 may be deposited over and/or on the semiconductor layer 212 (including the integrated circuit devices 214), and the metallization layer 218 and layer-to-layer connection structures 220 may be formed in the dielectric layer(s) 216. To form the interconnect layer 210, a deposition tool may be used to deposit a first dielectric layer 216 (e.g., using a physical vapor deposition (PVD) technique, an atomic layer deposition (ALD) technique, a chemical vapor deposition (CVD) technique, an oxidation technique, and/or another suitable deposition technique). In some implementations, a planarization tool may be used to planarize the first dielectric layer 216 after the first dielectric layer 216 is deposited. A deposition tool, an exposure tool, a developer tool, and/or an etch tool may be used to pattern the first dielectric layer 216 to form recesses in the first dielectric layer 216. A deposition tool may be used to deposit (e.g., using a PVD technique, an ALD technique, a CVD technique, an electroplating technique, and/or another suitable deposition technique) a first layer-to-layer connection structure 220 in the recesses. A deposition tool may be used to deposit a second dielectric layer 216 on the first dielectric layer 216, the second dielectric layer 216 may be patterned, and a first metallization layer 218 may be formed in the second dielectric layer 216 such that the first metallization layer 218 is electrically coupled with the first interconnect structure 220. Subsequent dielectric layers 216, metallization layers 218, and layer-to-layer connection structures 220 of the interconnect layer 210 may be formed in a similar manner.

As shown in FIG. 5D, the passivation layer 222 is formed over and/or on the topmost dielectric layer 216. A deposition tool may be used to deposit the passivation layer 222 using a PVD technique, an ALD technique, a CVD technique, an oxidation technique, and/or another suitable deposition technique. In some implementations, a planarization tool may be used to planarize the passivation layer 222 after the passivation layer 222 is deposited. The passivation layer 222 may be patterned to form recesses in the passivation layer 222, and the top metal pads 224 and the top metal vias 226 may be formed in the recesses. The top metal pads 224 may be formed such that the top metal pads 224 are electrically coupled and/or physically coupled to the topmost layer-to-layer connection structures 220 in the interconnect layer 210. The top metal vias 226 may be formed such that the top metal vias 226 are electrically coupled and/or physically coupled to the top metal pads 224.

As indicated above, FIGS. 5A-5D are provided as an example. Other examples may differ from what is described with regard to FIGS. 5A-5D.

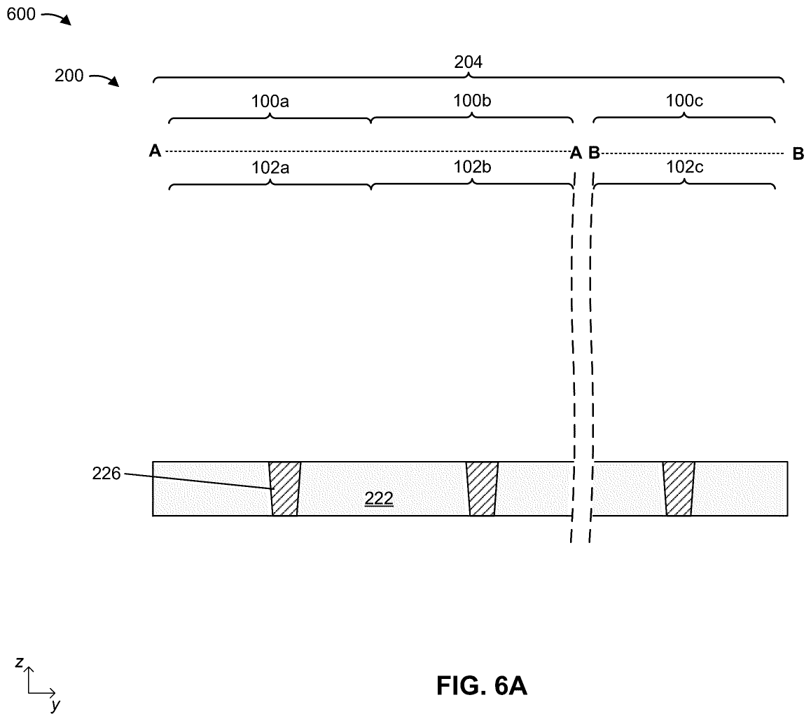

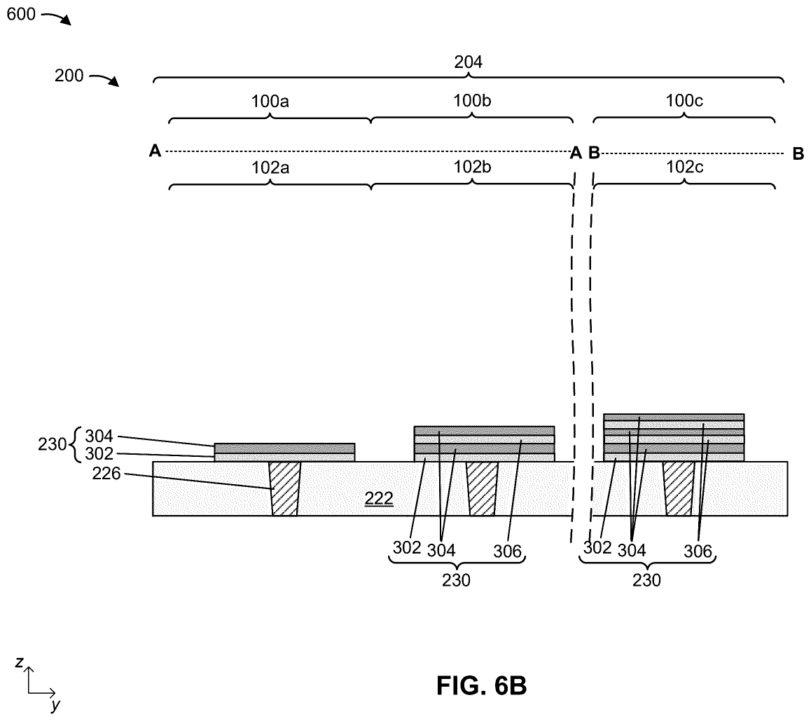

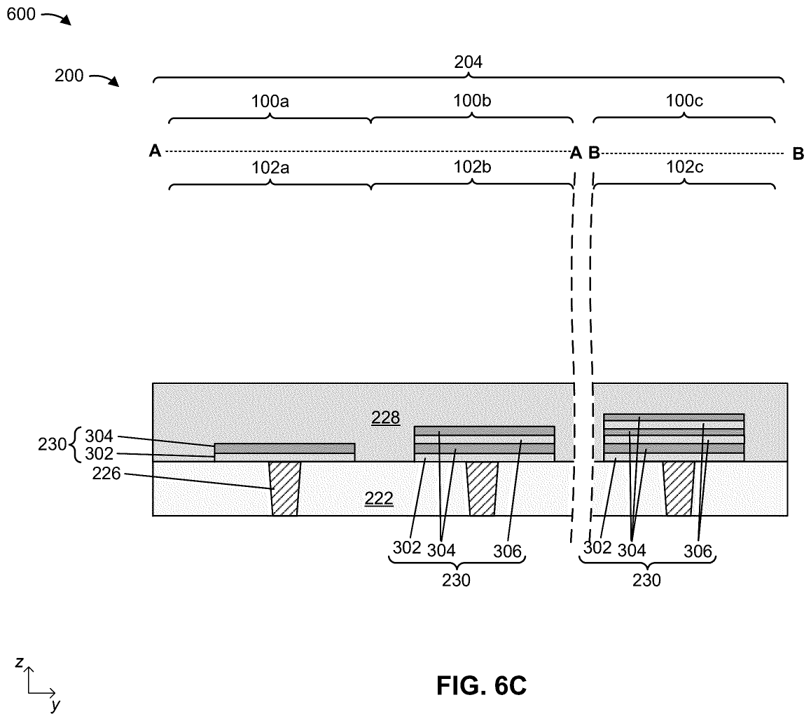

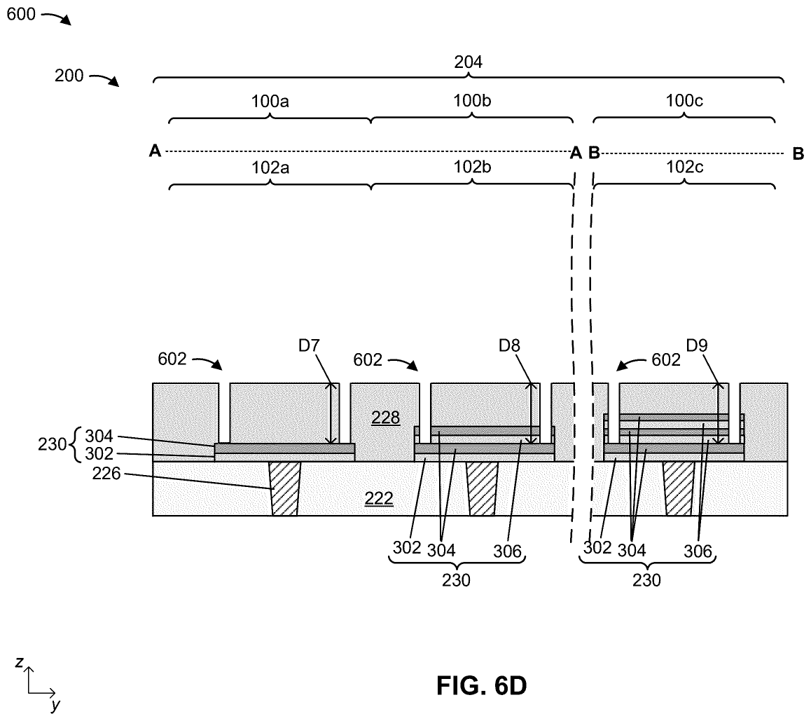

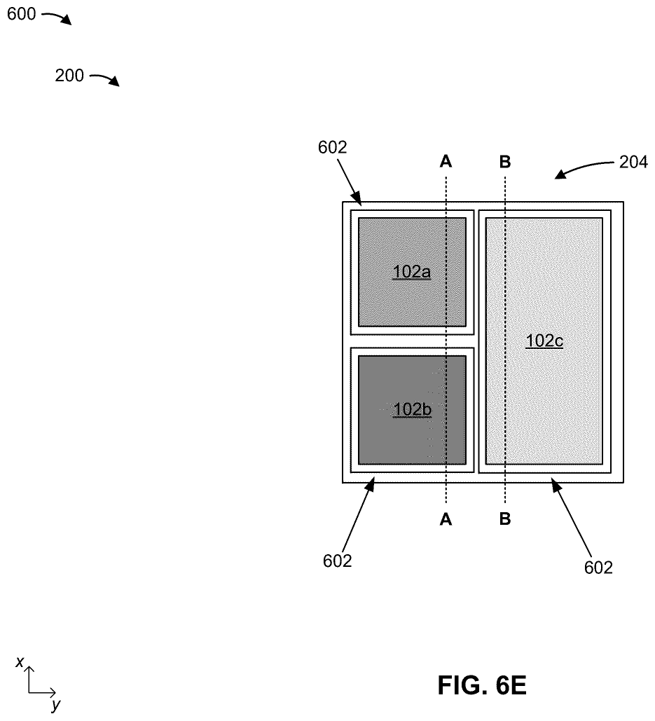

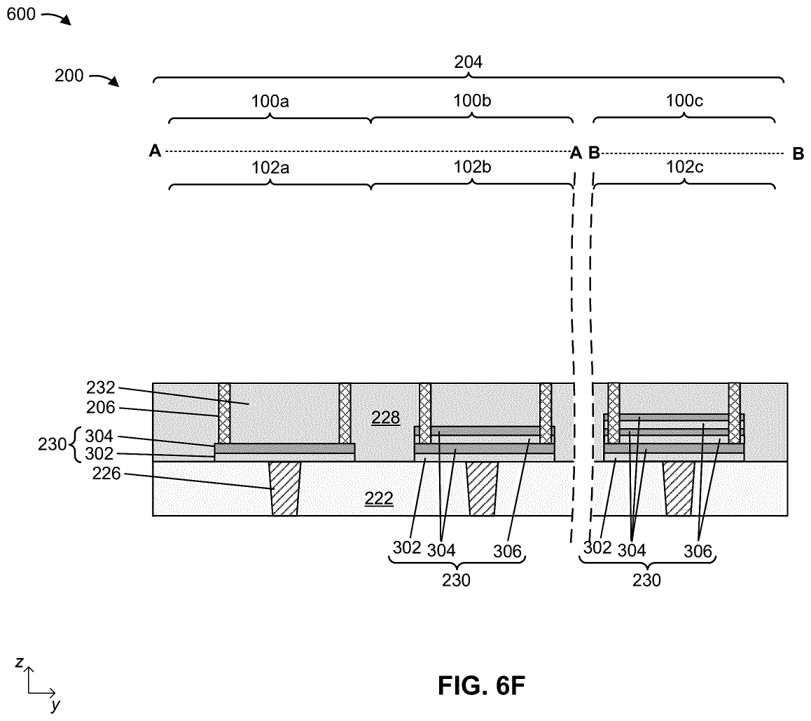

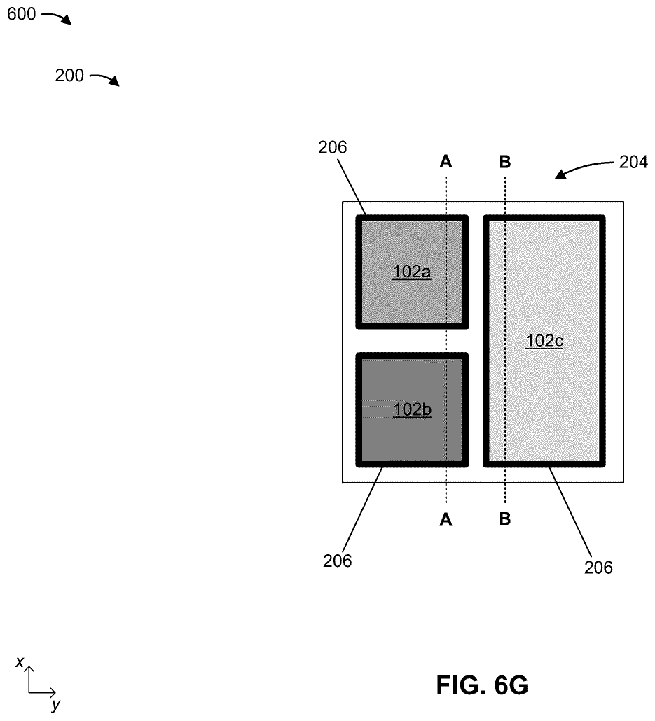

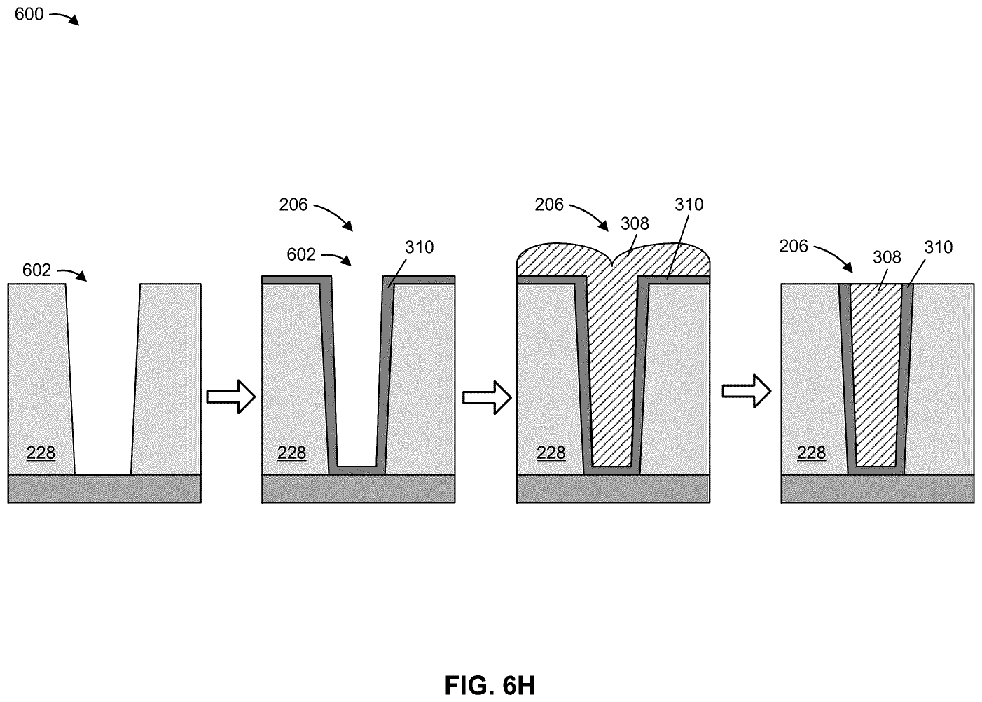

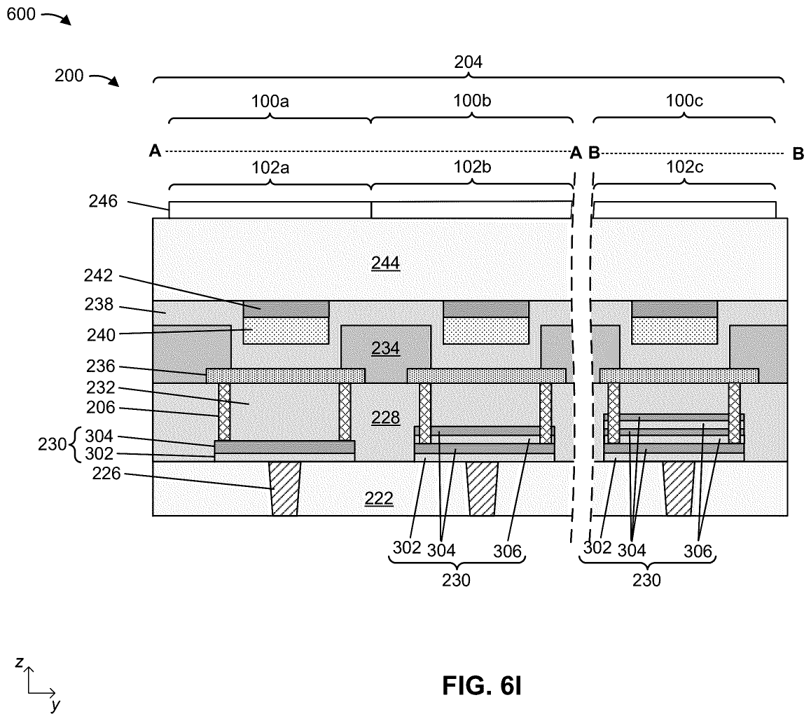

FIGS. 6A-6I are diagrams of an example implementation 600 of forming a portion of the semiconductor device 200 described herein. In particular, the example implementation 500 may include an example of forming the subpixels 102 of the display pixels 204 in the display pixel array 202 of the semiconductor device 200. In some implementations, one or more semiconductor processing tools may be used to perform one or more of the operations described in connection with the example implementation 600, such as a deposition tool, an exposure tool, a developer tool, an etch tool, a planarization tool, a plating tool, and/or another type of semiconductor processing tool.

Turning to FIG. 6A, one or more of the operations described in connection with the example implementation 600 are performed after the operations described in connection with FIGS. 5A-5D. For example, one or more of the operations described in connection with the example implementation 600 are performed after forming the device layer 208 and the interconnect layer 210 of the semiconductor device 200.

As shown in FIG. 6B, the first electrodes 230 (e.g., the bottom electrodes or anodes) of the subpixels 102a-102c of a display pixel 204 of the semiconductor device 200 are formed on the passivation layer 222 such that the first electrodes 230 are electrically connected to the top metal vias 226. The first electrodes 230 may be formed to different z-direction thicknesses for different subpixels. This enables different z-direction thicknesses for the resonant cavities for the subpixels to be achieved.

For example, the first electrode 230 for the subpixel 102c may be formed such that the z-direction thicknesses of the first electrode 230 for the subpixel 102c are greater than the z-direction thicknesses of the first electrode 230 for the subpixel 102b and the z-direction thicknesses of the first electrode 230 for the subpixel 102a because of the subpixel 102c being a blue subpixel that is configured to emit shorter wavelength light (e.g., blue light) than the subpixels 102a and 102b. The first electrode 230 for the subpixel 102c is formed such that the size of the resonant cavity for the subpixel 102c facilitates resonance of the wavelengths for the subpixel 102c.

As another example, the first electrode 230 for the subpixel 102b may be formed such that the z-direction thicknesses of the first electrode 230 for the subpixel 102b are greater than the z-direction thicknesses of the first electrode 230 for the subpixel 102a because of the subpixel 102b being a green subpixel that is configured to emit shorter wavelength light (e.g., green light) than the subpixels 102a (e.g., which may be configured to emit red light). The first electrode 230 for the subpixel 102b is formed such that the size of the resonant cavity for the subpixel 102b facilitates resonance of the wavelengths for the subpixel 102b.

As another example, the first electrode 230 for the subpixel 102a may be formed such that the z-direction thicknesses of the first electrode 230 for the subpixel 102a are less than the z-direction thicknesses of the first electrode 230 for the subpixel 102b and the z-direction thicknesses of the first electrode 230 for the subpixel 102c because of the subpixel 102a being a red subpixel that is configured to emit longer wavelength light (e.g., red light) than the subpixels 102b and 102c. The first electrode 230 for the subpixel 102a is formed such that the size of the resonant cavity for the subpixel 102a facilitates resonance of the wavelengths for the subpixel 102a.

A nitride layer 302 may first be formed on the passivation layer 222. The nitride layer 302 may include tantalum nitride (TaN) and/or another nitride-containing material. The nitride layer 302 may be included as a barrier layer for the first electrodes 230 and/or to promote adhesion between the first electrodes 230 and the passivation layer 222. A deposition tool may be used to deposit the nitride layer 302 using a PVD technique, an ALD technique, a CVD technique, an oxidation technique, and/or another suitable deposition technique. In some implementations, a planarization tool may be used to planarize the nitride layer 302 after the nitride layer 302 is deposited.

In some implementations, to form the first electrodes 230 of the subpixels 102a-102c, a layer stack may be formed on the nitride layer 302 and etched to form the first electrodes 230. For example, an alternating arrangement of metal layers 304 and nitride (e.g., titanium nitride (TiN)) layers 306 may be deposited on the nitride layer 302, the alternating arrangement of metal layers 304 and nitride layers 306 may be patterned and etched to define the first electrodes 230, and subsequent masking and etching operations may be performed to remove metal layers 304 and/or nitride layers 306 from the first electrodes 230 of one or more of the subpixels 102a-102c to form the first electrodes 230 of the one or more of the subpixels 102a-102c to a desired z-direction thickness. As an example, after etching the alternating arrangement of metal layers 304 and nitride layers 306 to define the first electrodes 230, the first electrode 230 of the subpixel 102c may be masked to enable the first electrodes 230 of the subpixels 102a and 102b to be etched to remove one or more metal layers 304 and/or one or more nitride layers 306 from the first electrodes 230 of the subpixels 102a and 102b.

In some implementations, to form the first electrodes 230 of the subpixels 102a-102c, a layer of aluminum is formed on the nitride layer 302 and etched to form a first metal layer 304 for the first electrodes 230 of the subpixels 102a-102c. The first electrode 230 for the subpixel 102a is then masked, and additional metal layers 304 and nitride layers 306 are deposited on the first metal layer 304 for the subpixels 102b and 102c. The first electrode 230 for the subpixel 102b is then masked, and the remaining metal layers 304 and nitride layers 306 for the subpixel 102c are then deposited.

A deposition tool may be used to deposit the metal layers 304 and the nitride layers 306 of the first electrodes 230 using a PVD technique, an ALD technique, a CVD technique, and/or another suitable deposition technique. In some implementations, a planarization tool may be used to planarize one or more of the metal layers 304 and/or one or more of the nitride layers 306.

As shown in FIG. 6C, the cavity oxide layer 228 is formed on the first electrodes 230 of the subpixels 102a-102c such that the first electrodes 230 are covered by the cavity oxide layer 228. A deposition tool may be used to deposit the cavity oxide layer 228 using a PVD technique, an ALD technique, a CVD technique, an oxidation technique, and/or another suitable deposition technique. In some implementations, a planarization tool may be used to planarize the cavity oxide layer 228 after the cavity oxide layer 228 is deposited.

As shown in FIG. 6D, recesses 602 are formed in the cavity oxide layer 228 above and/or on the first electrodes 230 of the subpixels 102a-102c. For example, a recess 602 may be formed above and/or on the first electrode 230 of the subpixel 102a, a recess 602 may be formed above and/or on the first electrode 230 of the subpixel 102b, a recess 602 may be formed above and/or on the first electrode 230 of the subpixel 102c, and so on.

The recess 602 above first electrode 230 of the subpixel 102a may be formed to the metal layer 304 of the first electrode 230 of the subpixel 102a. Alternatively, the recess 602 above first electrode 230 of the subpixel 102a may be formed such that the recess 602 extends into the metal layer 304 of the first electrode 230 of the subpixel 102a.

The recess 602 above first electrode 230 of the subpixel 102b may be formed such that the recess 602 extends into one or more metal layers 304 and/or into one or more nitride layers 306 of the first electrode 230 of the subpixel 102b. Thus, the bottom of the recess 602 is below a top surface of the first electrode 230 of the subpixel 102b.

The recess 602 above first electrode 230 of the subpixel 102c may be formed such that the recess 602 extends into one or more metal layers 304 and/or into one or more nitride layers 306 of the first electrode 230 of the subpixel 102c. Thus, the bottom of the recess 602 is below a top surface of the first electrode 230 of the subpixel 102c.

As further shown in FIG. 6D, the recess 602 above first electrode 230 of the subpixel 102a may be formed to a first depth (indicated in FIG. 6D as dimension D7), the recess 602 above first electrode 230 of the subpixel 102b may be formed to a second depth (indicated in FIG. 6D as dimension D8), and the recess 602 above first electrode 230 of the subpixel 102c may be formed to a third depth (indicated in FIG. 6D as dimension D9).

In some implementations, the first depth, the second depth, and the third depth are approximately a same depth such that the bottom surfaces of the recesses 602 are approximately co-planar and located at approximately a same z-direction depth in the semiconductor device 200 (e.g., dimension D7, dimension D8, and dimension D9 are approximately equal). In these implementations, the recess 602 above first electrode 230 of the subpixel 102c may extend further or deep into the first electrode 230 of the subpixel 102c than the recess 602 above first electrode 230 of the subpixel 102b extends into the first electrode 230 of the subpixel 102b, and/or may extend further or deeper into the first electrode 230 of the subpixel 102c than the recess 602 above first electrode 230 of the subpixel 102a extends into the first electrode 230 of the subpixel 102a.

In some implementations, the first depth, the second depth, and the third depth are different depths such that the bottom surfaces of the recesses 602 are located at different z-direction depths in the semiconductor device 200 (e.g., dimension D7, dimension D8, and dimension D9 are different). In some implementations, the recesses 602 may extend approximately a same distance into the first electrodes 230 of the subpixels 102a-102c.

In some implementations, a pattern in a photoresist layer is used to etch the cavity oxide layer 228, one or more metal layers 304 of one or more first electrodes 230, and/or one or more nitride layers 306 of one or more first electrodes 230 to form the recesses 602. In these implementations, a deposition tool may be used to form the photoresist layer on the cavity oxide layer 228. An exposure tool may be used to expose the photoresist layer to a radiation source to pattern the photoresist layer. A developer tool may be used to develop and remove portions of the photoresist layer to expose the pattern. An etch tool may be used to etch the cavity oxide layer 228, one or more metal layers 304 of one or more first electrodes 230, and/or one or more nitride layers 306 of one or more first electrodes 230 based on the pattern to form the recesses 602. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 602 based on a pattern.

In some implementations, a cyclic etch technique is used to form the recesses 602 to have a relatively high aspect ratio between the depth of the recesses 602 and the lateral width of the recesses 602. For example, a cyclic etch technique is used to form the recesses 602 such that the recesses 602 have an aspect ratio between the depth of the recesses 602 and the lateral width of the recesses 602 that is at least approximately 8:1. However, other values for the aspect ratio of the recesses 602 are within the scope of the present disclosure.

In some implementations, a deep reactive ion etch technique (sometimes referred to as a “BOSCH” etch technique) may be used to achieve the high aspect ratio for the recesses 602. A deep reactive ion etch technique is a cyclic etch technique in which a plurality of deposition and etch cycles are performed using protective liners to minimize lateral etching. For example, a deep reactive ion etch cycle may include etching a recess 602 to a first depth in the cavity oxide layer 228, forming a protective liner on the sidewalls and bottom surface of the recess 602, etching the protective liner to remove the protective liner from the bottom surface of the recess 602, and etching the bottom of the recess 602 to increase the depth of the recess 602 to a second depth while the protective liner protects the sidewalls of the recess 602 from lateral etching. Additional cycles may be performed to achieve a particular depth for the recesses 602.

As shown in a top view of the semiconductor device 200 in FIG. 6E, the recesses 602 may include closed-loop recesses 602 (e.g., closed-loop trenches) around the perimeters of the subpixels 102a-102c. The closed-loop recesses 602 may be formed around the perimeters of the subpixels 102a-102c.

As shown in FIG. 6F, isolation structures 206 are formed in the recesses 602. For example, an isolation structure 206 may be formed in the recess 602 above the first electrode 230 of the subpixel 102a such that the isolation structure lands on the metal layer 304 of the first electrode 230 of the subpixel 102a. Alternatively, the isolation structure 206 for the subpixel 102a may be formed in the recess 602 above the first electrode 230 of the subpixel 102a such that the bottom surface of the isolation structure extends into the metal layer 304 of the first electrode 230 of the subpixel 102a.

As another example, an isolation structure 206 may be formed in the recess 602 above the first electrode 230 of the subpixel 102b such that the isolation structure lands on the metal layer 304 of the first electrode 230 of the subpixel 102b. Alternatively, the isolation structure 206 for the subpixel 102b may be formed in the recess 602 above the first electrode 230 of the subpixel 102b such that the bottom surface of the isolation structure extends into one or more metal layers 304 of the first electrode 230 of the subpixel 102a and/or extends into one or more nitride layers 306 of the first electrode 230 of the subpixel 102b.

As another example, an isolation structure 206 may be formed in the recess 602 above the first electrode 230 of the subpixel 102b such that the isolation structure lands on the metal layer 304 of the first electrode 230 of the subpixel 102b. Alternatively, the isolation structure 206 for the subpixel 102b may be formed in the recess 602 above the first electrode 230 of the subpixel 102b such that the bottom surface of the isolation structure extends into one or more metal layers 304 of the first electrode 230 of the subpixel 102b and/or extends into one or more nitride layers 306 of the first electrode 230 of the subpixel 102b.

As another example, an isolation structure 206 may be formed in the recess 602 above the first electrode 230 of the subpixel 102c such that the isolation structure lands on the metal layer 304 of the first electrode 230 of the subpixel 102c. Alternatively, the isolation structure 206 for the subpixel 102c may be formed in the recess 602 above the first electrode 230 of the subpixel 102c such that the bottom surface of the isolation structure extends into one or more metal layers 304 of the first electrode 230 of the subpixel 102c and/or extends into one or more nitride layers 306 of the first electrode 230 of the subpixel 102c.

An isolation structure 206 may include a trench (e.g., a DTI structure) and/or another type of structure that is elongated in the z-direction (e.g., a vertical direction) in the semiconductor device 200. A deposition tool may be used to deposit an isolation structure 206 using a CVD technique, a PVD technique, an ALD technique, an electroplating technique, and/or another suitable deposition technique. In some implementations, a planarization tool is used to perform a planarization operation (e.g., a chemical-mechanical planarization (CMP) operation) to planarize an isolation structure 206 after the isolation structure 206 is deposited.

As shown in FIG. 6G, the isolation structures 206 may each include a closed-loop isolation structure that fully encircles the perimeter of an associated subpixel of the subpixels 102a-102c. The top view shape of the isolation structure 206 may conform to the shape of the closed-loop recess 602 in which the isolation structures 206 was formed, and may include a closed-loop isolation ring, a closed loop isolation square, a closed-loop isolation rectangle, and/or another closed-loop shape.

FIG. 6H illustrates an example process for forming an isolation structure 206 in a recess 602. As shown in FIG. 6H, one or more liners 310 may be conformally deposited on the sidewalls and on the bottom surface of the recess 602 such that the one or more liners 310 conform to the profile of the recess 602. A deposition tool may be used to deposit the one or more liners 310 using a conformal deposition technique such as ALD or CVD. The one or more liners 310 may include a tantalum nitride (TaN) barrier layer, a tantalum (Ta) barrier layer, a copper (Cu) see layer, and/or another type of liner.

As further shown in FIG. 6H, the recess 602 is then filled with material on the one or more liners 310 to form an isolation layer 308 in the recess 602. The isolation layer 308 may include copper (Cu), tungsten (W), titanium nitride (TiN), and/or another suitable material. A deposition tool may be used to deposit the material of the isolation layer 308 using a CVD technique, a PVD technique, an ALD technique, an electroplating technique, and/or another suitable deposition technique.

As further shown in FIG. 6H, the material of the isolation layer 308 may be deposited such that the excess material of the isolation layer 308 extends above the top of the recess 602 and/or over the top surface of the cavity oxide layer 228. This ensures that the recess 602 is fully filled with the material of the isolation layer 308 so as to minimize the likelihood of seams and/or voids forming the isolation layer 308. Accordingly, a planarization tool is used to perform a planarization operation (e.g., a CMP operation) to planarize the isolation layer 308 after the isolation layer 308 is deposited. The planarization operation may also be performed to remove material of the one or more liners 310 from the top surface of the cavity oxide layer 228. The planarization operation results in the top surface of the isolation layer 308 being approximately co-planar with the top surface of the cavity oxide layer 228.

As shown in FIG. 6I, the remaining layers of the subpixels 102 may be provided on the cavity oxide layer 228 and above the isolation structures 206. In some implementations, the substrate layers 236, the pixel define layers 234 and 238, the light generation film stacks 240, the second electrodes 242, the passivation layer 244, and the color filters 246 may be formed as an integrated unit that is placed on the cavity oxide layer 228 after manufacturing. In some implementations, one or more of the substrate layers 236, the pixel define layers 234 and 238, the light generation film stacks 240, the second electrodes 242, the passivation layer 244, and/or the color filters 246 are formed on the cavity oxide layer 228.

As indicated above, FIGS. 6A-6I are provided as an example. Other examples may differ from what is described with regard to FIGS. 6A-6I.

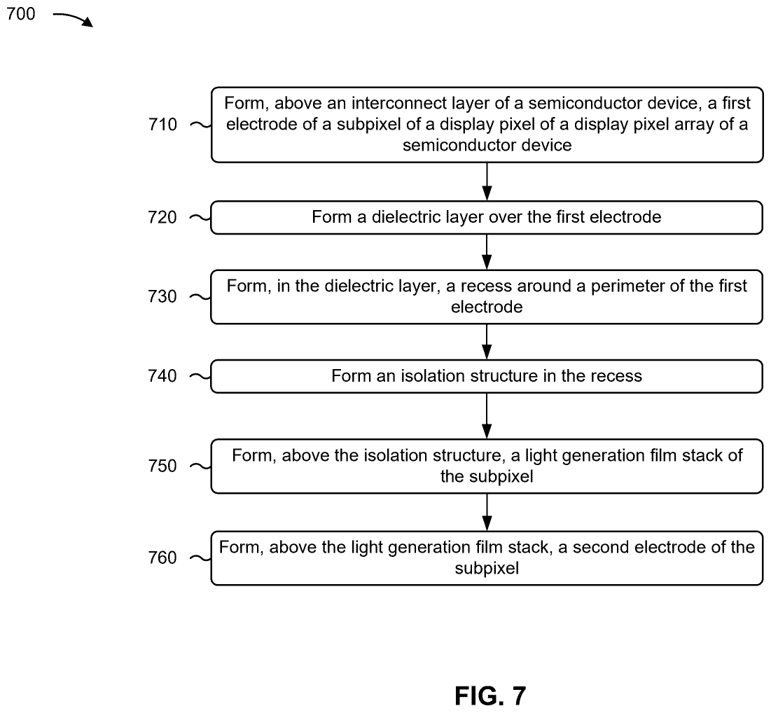

FIG. 7 is a flowchart of an example process 700 associated with forming a semiconductor device described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIG. 7, process 700 may include forming, above an interconnect layer of a semiconductor device, a first electrode of a subpixel of a display pixel of a display pixel array of the semiconductor device (block 710). For example, one or more semiconductor processing tools may be used to form, above an interconnect layer 210 of a semiconductor device 200, a first electrode 230 of a subpixel 102 of a display pixel 204 of a display pixel array 202 of the semiconductor device, as described herein.

As further shown in FIG. 7, process 700 may include forming a dielectric layer over the first electrode (block 720). For example, one or more semiconductor processing tools may be used to form a cavity oxide layer 228 over the first electrode 230, as described herein.

As further shown in FIG. 7, process 700 may include forming, in the dielectric layer, a recess around a perimeter of the first electrode (block 730). For example, one or more semiconductor processing tools may be used to form, in the cavity oxide layer 228, a recess 602 around a perimeter of the first electrode 230, as described herein.

As further shown in FIG. 7, process 700 may include forming an isolation structure in the recess (block 740). For example, one or more semiconductor processing tools may be used to form an isolation structure 206 in the recess 602, as described herein. In some implementations, the isolation structure 206 defines a resonance cavity 232, of the subpixel 102, above the first electrode 230.

As further shown in FIG. 7, process 700 may include forming, above the isolation structure, a light generation film stack of the subpixel (block 750). For example, one or more semiconductor processing tools may be used to form, above the isolation structure 206, a light generation film stack 240, as described herein.

As further shown in FIG. 7, process 700 may include forming, above the light generation film stack, a second electrode of the subpixel (block 760). For example, one or more semiconductor processing tools may be used to form, above the light generation film stack 240, a second electrode 242, as described herein.

Process 700 may include additional implementations, such as any single implementation or any combination of implementations described below and/or in connection with one or more other processes described elsewhere herein.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

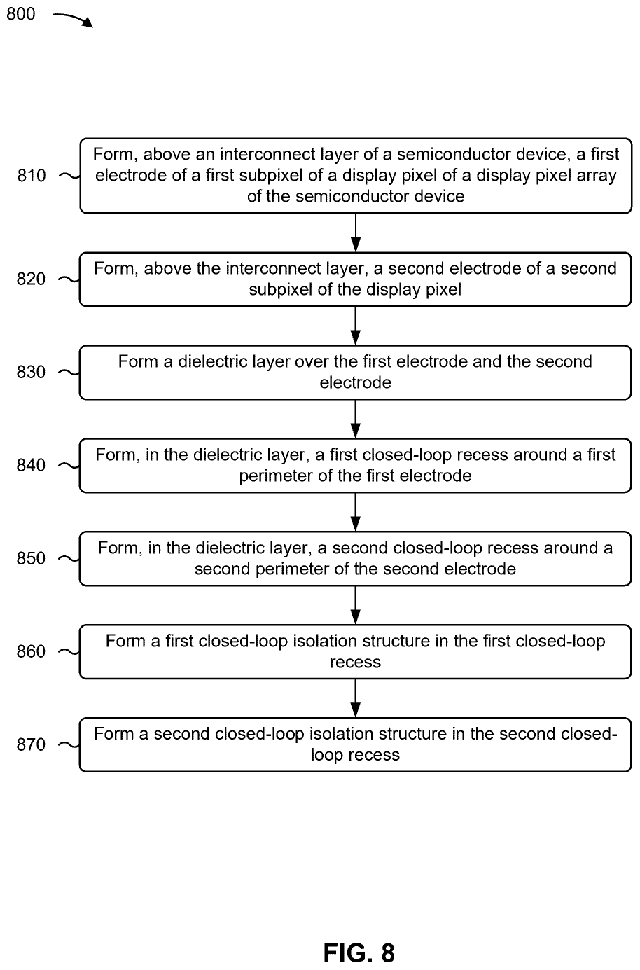

FIG. 8 is a flowchart of an example process 800 associated with forming a semiconductor device described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIG. 8, process 800 may include forming, above an interconnect layer of a semiconductor device, a first electrode of a first subpixel of a display pixel of a display pixel array of the semiconductor device (block 810). For example, one or more semiconductor processing tools may be used to form, above an interconnect layer 210 of a semiconductor device 200, a first electrode 230 of a first subpixel 102 of a display pixel 204 of a display pixel array 202 of the semiconductor device, as described herein.

As further shown in FIG. 8, process 800 may include forming, above the interconnect layer, a second electrode of a second subpixel of the display pixel (block 820). For example, one or more semiconductor processing tools may be used to form, above the interconnect layer 210, a second electrode (e.g., another first electrode 230) of a second subpixel 102 of the display pixel 204, as described herein.

As further shown in FIG. 8, process 800 may include forming a dielectric layer over the first electrode and the second electrode (block 830). For example, one or more semiconductor processing tools may be used to form a dielectric layer (e.g., a cavity oxide layer 228) over the first electrode 230 and the second electrode (e.g., the other first electrode 230), as described herein.

As further shown in FIG. 8, process 800 may include forming, in the dielectric layer, a first closed-loop recess around a first perimeter of the first electrode (block 840). For example, one or more semiconductor processing tools may be used to form, in the dielectric layer, a first closed-loop recess 602 around a first perimeter of the first electrode 230, as described herein.

As further shown in FIG. 8, process 800 may include forming, in the dielectric layer, a second closed-loop recess around a second perimeter of the second electrode (block 850). For example, one or more semiconductor processing tools may be used to form, in the dielectric layer, a second closed-loop recess 602 around a second perimeter of the second electrode (e.g., the other first electrode 230), as described herein.

As further shown in FIG. 8, process 800 may include forming a first closed-loop isolation structure in the first closed-loop recess (block 860). For example, one or more semiconductor processing tools may be used to form a first closed-loop isolation structure 206 in the first closed-loop recess 602, as described herein. In some implementations, the first closed-loop isolation structure 206 defines a first dielectric resonance cavity 232 above the first electrode 230.

As further shown in FIG. 8, process 800 may include forming a second closed-loop isolation structure in the second closed-loop recess (block 870). For example, one or more semiconductor processing tools may be used to form a second closed-loop isolation structure 206 in the second closed-loop recess 602, as described herein. In some implementations, the second closed-loop isolation structure 206 defines a second dielectric resonance cavity 232 above the first electrode 230.

Process 800 may include additional implementations, such as any single implementation or any combination of implementations described below and/or in connection with one or more other processes described elsewhere herein.

In a first implementation, forming the first electrode 230 includes forming the first electrode 230 such that a first top surface of the first electrode 230 is located at a first height in the semiconductor device 200, and forming the second electrode (e.g., the other first electrode 230) includes forming the second electrode such that a second top surface of the second electrode is located at a second height in the semiconductor device 200, where the first height is greater than the second height.

In a second implementation, alone or in combination with the first implementation, forming the first closed-loop recess 602 includes forming the first closed-loop recess 602 to a first depth (e.g., a dimension D7, a dimension D8, a dimension D9) in the dielectric layer (e.g., the cavity oxide layer 228), and forming the second closed-loop recess 602 includes forming the second closed-loop recess 602 to a second depth (e.g., a dimension D7, a dimension D8, a dimension D9) in the dielectric layer, the first depth and the second depth are approximately a same depth.

In a third implementation, alone or in combination with one or more of the first and second implementations, forming the first closed-loop recess 602 includes forming the first closed-loop recess 602 such that the first closed-loop recess 602 extends into the first electrode 230.

In a fourth implementation, alone or in combination with one or more of the first through third implementations, process 800 includes planarizing the first closed-loop isolation structure 206 and the second closed-loop isolation structure 206 such that a first top surface of the first closed-loop isolation structure 206 and a second top surface of the second closed-loop isolation structure 206 are approximately co-planar.

In a fifth implementation, alone or in combination with one or more of the first through fourth implementations, process 800 includes providing a first organic light generation film stack 240 above the first dielectric resonance cavity 232, and providing a second organic light generation film stack 240 above the second dielectric resonance cavity 232.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a semiconductor device (e.g., a microdisplay device) includes isolation structures around subpixels of at least a portion of the display pixels in the display pixel array of the semiconductor device. The isolation structures (e.g., isolation trenches, isolation rings) confine the light generated by the subpixels, enabling the light generated by the subpixels to be highly contained and collimated. Thus, the isolation structures reduce lateral dispersion of the light emitted by the subpixels, which reduces the amount of color mixing between the subpixels. This enables the display pixel array to generate images and/or video with highly accurate color representation and high contrast, among other examples.

As described in greater detail above, some implementations described herein provide a semiconductor device. The semiconductor device includes a display pixel array that includes a plurality of display pixels. A display pixel, of the plurality of display pixels, includes a first electrode, a dielectric region above the first electrode, a light generation film stack above the dielectric region, a second electrode above the light generation film stack, and an isolation structure laterally surrounding the dielectric region.

As described in greater detail above, some implementations described herein provide a semiconductor device. The semiconductor device includes a semiconductor substrate. The semiconductor device includes a plurality of integrated circuit devices in the semiconductor substrate. The semiconductor device includes an interconnect layer above the semiconductor substrate. The semiconductor device includes a display pixel array, above the interconnect layer, that includes a plurality of display pixels. A display pixel, of the plurality of display pixels, includes plurality of subpixels. Each subpixel of the plurality of subpixels includes a bottom electrode, a resonance region, above the bottom electrode, a light generation film stack above the resonance region, a top electrode above the light generation film stack, and an isolation structure laterally surrounding the resonance region.

As described in greater detail above, some implementations described herein provide a method. The method includes forming, above an interconnect layer of a semiconductor device, a first electrode of a first subpixel of a display pixel of a display pixel array of the semiconductor device. The method includes forming, above the interconnect layer, a second electrode of a second subpixel of the display pixel. The method includes forming a dielectric layer over the first electrode and the second electrode. The method includes forming, in the dielectric layer, a first closed-loop recess around a first perimeter of the first electrode. The method includes forming, in the dielectric layer, a second closed-loop recess around a second perimeter of the second electrode. The method includes forming a first closed-loop isolation structure in the first closed-loop recess, where the first closed-loop isolation structure defines a first dielectric resonance cavity above the first electrode. The method includes forming a second closed-loop isolation structure in the second closed-loop recess, where the second closed-loop isolation structure defines a second dielectric resonance cavity above the first electrode.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a display pixel array comprising a plurality of display pixels,
wherein a display pixel, of the plurality of display pixels, comprises:
a first electrode;
a dielectric region above the first electrode;
a light generation film stack above the dielectric region;
a second electrode above the light generation film stack; and
an isolation structure laterally surrounding the dielectric region.

2. The semiconductor device of claim 1, wherein a bottom surface of the isolation structure extends into the first electrode.

3. The semiconductor device of claim 1, wherein a bottom surface of the isolation structure is on top of the first electrode.

4. The semiconductor device of claim 1, wherein a vertical thickness of the isolation structure is approximately equal to a thickness of the dielectric region.

5. The semiconductor device of claim 1, wherein the isolation structure comprises a an isolation trench, around the dielectric region, that includes one or more metal-containing materials.

6. The semiconductor device of claim 5, wherein the isolation structure further comprises one or more liners on sidewalls and on a bottom surface of the copper isolation trench.

7. The semiconductor device of claim 6, wherein the one or more liners comprise at least one of:
a tantalum nitride (TaN) barrier layer, or
a copper (Cu) layer.

8. A semiconductor device, comprising:
a semiconductor substrate;
a plurality of integrated circuit devices in the semiconductor substrate;
an interconnect layer above the semiconductor substrate; and
a display pixel array, above the interconnect layer, comprising a plurality of display pixels,
wherein a display pixel, of the plurality of display pixels, comprises a plurality of subpixels,
wherein each subpixel of the plurality of subpixels comprises:
a bottom electrode;
a resonance region above the bottom electrode;
a light generation film stack above the resonance region;
a top electrode above the light generation film stack; and
an isolation structure laterally surrounding the resonance region.

9. The semiconductor device of claim 8, wherein a first isolation structure of a first subpixel of the plurality of subpixels has a first vertical thickness;
wherein a second isolation structure of a second subpixel of the plurality of subpixels has a second vertical thickness; and
wherein the first vertical thickness and the second vertical thickness are approximately a same thickness.

10. The semiconductor device of claim 8, wherein a first bottom electrode of a first subpixel of the plurality of subpixels has a first vertical thickness;
wherein a second bottom electrode of a second subpixel of the plurality of subpixels has a second vertical thickness; and
wherein the first vertical thickness and the second vertical thickness are different thicknesses.

11. The semiconductor device of claim 8, wherein a first bottom surface of a first resonance region of a first subpixel of the plurality of subpixels is located closer to the interconnect layer than a second bottom surface of a second resonance region of a second subpixel of the plurality of subpixels.

12. The semiconductor device of claim 11, wherein a third top surface of a first isolation structure of the first subpixel is approximately co-planar with the first bottom surface of the first resonance region; and
wherein a fourth top surface of a second isolation structure of the second subpixel is located closer to the interconnect layer than the second bottom surface of the second resonance region.

13. The semiconductor device of claim 8, wherein a first bottom electrode of a first subpixel of the plurality of subpixels comprises a first metal layer;
wherein a second bottom electrode of a second subpixel of the plurality of subpixels comprises:
a second metal layer;
a metal nitride layer on the second metal layer; and
a third metal layer on the metal nitride layer;
wherein a first isolation ring of the first subpixel is located on a top surface of the first metal layer; and
wherein a second metal isolation structure of the second subpixel is located on the second metal layer and extends through the metal nitride layer and the third metal layer.

14. The semiconductor device of claim 8, wherein a first bottom electrode of a first subpixel of the plurality of subpixels comprises:
a first plurality of metal layers; and
one or more first metal nitride layers;
wherein a second bottom electrode of a second subpixel of the plurality of subpixels comprises:
a second plurality of metal layers; and
one or more second metal nitride layers; and
wherein a first quantity of metal layers in the first plurality of metal layers is greater than a second quantity of metal layers in the second plurality of metal layers.

15. A method, comprising:
forming, above an interconnect layer of a semiconductor device, a first electrode of a first subpixel of a display pixel of a display pixel array of the semiconductor device;
forming, above the interconnect layer, a second electrode of a second subpixel of the display pixel;
forming a dielectric layer over the first electrode and the second electrode;
forming, in the dielectric layer, a first closed-loop recess around a first perimeter of the first electrode;
forming, in the dielectric layer, a second closed-loop recess around a second perimeter of the second electrode;
forming a first closed-loop isolation structure in the first closed-loop recess,
wherein the first closed-loop isolation structure defines a first dielectric resonance cavity above the first electrode; and
forming a second closed-loop isolation structure in the second closed-loop recess,
wherein the second closed-loop isolation structure defines a second dielectric resonance cavity above the first electrode.

16. The method of claim 15, wherein forming the first electrode comprises forming the first electrode such that a first top surface of the first electrode is located at a first height in the semiconductor device; and
wherein forming the second electrode comprises forming the second electrode such that a second top surface of the second electrode is located at a second height in the semiconductor device,
wherein the first height is greater than the second height.

17. The method of claim 15, wherein forming the first closed-loop recess comprises forming the first closed-loop recess to a first depth in the dielectric layer; and
wherein forming the second closed-loop recess comprises forming the second closed-loop recess to a second depth in the dielectric layer,
wherein the first depth and the second depth are approximately a same depth.

18. The method of claim 15, wherein forming the first closed-loop recess comprises forming the first closed-loop recess such that the first closed-loop recess extends into the first electrode.

19. The method of claim 15, further comprising:
planarizing the first closed-loop isolation structure and the second closed-loop isolation structure such that a first top surface of the first closed-loop isolation structure and a second top surface of the second closed-loop isolation structure are approximately co-planar.

20. The method of claim 15, further comprising:
providing a first organic light generation film stack above the first dielectric resonance cavity; and
providing a second organic light generation film stack above the second dielectric resonance cavity.
